(19) United States
(12) Patent Application Publication
(10) Pub. No.: US 2025/0359377 A1
(43) Pub. Date: Nov. 20, 2025

(54) IMAGE SENSOR

(71) Applicant: Samsung Electronics Co., Ltd., Suwon-si (KR)

(72) Inventors: Hyunkyu Choi, Suwon-si (KR); Jongsu Yoon, Suwon-si (KR); YUN KI LEE, Suwon-si (KR)

(21) Appl. No.: 19/095,299

(22) Filed: Mar. 31, 2025

(30) Foreign Application Priority Data
May 17, 2024 (KR) 10-2024-0064746

(51) Int. Cl. H10F 39/00; H10F 39/18

(52) U.S. Cl. CPC H10F 39/807; H10F 39/18; H10F 39/8053; H10F 39/8063

(57) ABSTRACT

An image sensor includes a substrate, a first photodiode disposed in the substrate, a second photodiode disposed in the substrate, wherein the second photodiode is adjacent to the first photodiode and is different from the first photodiode in planar area, a pixel isolation pattern that is disposed between the first and second photodiodes, a color filter disposed continuously above the first and second photodiodes, and a grid pattern that surrounds at least a part of the color filter. The color filter comprises a first portion overlapping the first photodiode in a first direction perpendicular to an upper surface of the substrate and a second portion overlapping the second photodiode in the first direction. A thickness of a junction portion where the first and second portions contact each other in the first direction corresponds to a thickness of one of the first and second portions.

### CROSS-REFERENCE TO RELATED APPLICATION

This application claims priority to and the benefit of Korean Patent Application No. 10-2024-0064746 filed in the Korean Intellectual Property Office on May 17, 2024, the entire contents of which are incorporated herein by reference.

### BACKGROUND OF THE DISCLOSURE

### 1. Field

The present disclosure relates to an image sensor.

### 2. Description of the Related Art

A complementary metal-oxide semiconductor (CMOS) image sensor is a solid imaging device using a CMOS. Compared to charge-coupled device (CCD) image sensors with high voltage analog circuits, the CMOS image sensor has advantages of low manufacturing cost and low power consumption due to the small size of the device. Therefore, the CMOS image sensor is installed in home appliances including portable devices such as smart phones and digital cameras.

A pixel array that forms the CMOS image sensor includes a photodiode for each pixel. The photodiode generates an electric signal that varies depending on the amount of incident light, and the CMOS image sensor processes the electrical signal to synthesize an image.

Recently, the CMOS image sensor may include a plurality of photodiodes with different areas or sensitivities to achieve a wide dynamic range (WDR).

Accordingly, the arrangement shape of the grid pattern for improving the sensitivity of plurality of photo diodes having different areas is desirable.

### SUMMARY

Embodiments are intended to provide an image sensor with improved optical characteristics.

According to an aspect of the present disclosure, an image sensor includes a substrate, a first photodiode disposed in the substrate, a second photodiode disposed in the substrate, wherein the second photodiode is adjacent to the first photodiode and is different from the first photodiode in planar area, a pixel isolation pattern that is disposed between the first photodiode and the second photodiode, a color filter disposed continuously above the first photodiode and the second photodiode, and a grid pattern that surrounds at least a part of the color filter. The color filter comprises a first portion overlapping the first photodiode in a first direction perpendicular to an upper surface of the substrate and a second portion overlapping the second photodiode in the first direction. A thickness of a junction portion where the first portion and the second portion of the color filter contact each other in the first direction corresponds to a thickness, in the first direction, of one of the first portion and second portion.

According to an aspect of the present disclosure, an image sensor includes a substrate, a first photodiode disposed in the substrate, a second photodiode disposed in the substrate, wherein the second photodiode is adjacent to the first photodiode and is different from the first photodiode in planar area, a pixel isolation pattern that is disposed between the first photodiode and the second photodiode, a color filter disposed continuously above the first photodiode and the second photodiode, and a grid pattern that surrounds at least a part of the color filter. The color filter comprises a first portion overlapping the first photodiode and a second portion overlapping the second photodiode. The grid pattern comprises a first pattern portion and a second pattern portion spaced apart from each other to define a first open portion of the grid pattern. Each of the first and second pattern portions is disposed between the first and second portions of the color filter. A junction portion at which the first portion and the second portion contact each other is disposed in the first open portion of the grid pattern.

According to an aspect of the present disclosure, an image sensor includes a substrate including a first side and a second side that face each other, a first photodiode disposed in the substrate, a second photodiode disposed in the substrate, wherein the second photodiode is adjacent to the first photodiode and is different from the first photodiode in planar area, a pixel isolation pattern that is disposed between the first photodiode and the second photodiode, a color filter disposed on the first side of the substrate and disposed continuously above the first photodiode and the second photodiode, a grid pattern that surrounds at least a part of the color filter, and a micro lens layer disposed on the color filter. The color filter comprises a first portion overlapping the first photodiode in a first direction perpendicular to the first side of the substrate and a second portion overlapping the second photodiode in the first direction. A thickness of a junction portion where the first portion and the second portion of the color filter contact each other in the first direction is greater than or substantially equal to a thickness, in the first direction, of the grid pattern. The micro lens layer includes a first micro lens disposed on the first portion of the color filter, and a second micro lens disposed on the second portion of the color filter and having a height that is different from a height of the first micro lens.

According to the embodiments, the amount of light lost by the grid pattern can be minimized by a photodiode having a relatively narrow light receiving area among a plurality of photodiodes having different areas by variously changing the arrangement of the grid pattern.

Accordingly, the sensitivity of the photodiode with the relatively narrow light receiving area among the plurality of photodiodes can be improved.

### BRIEF DESCRIPTION OF THE DRAWINGS

FIG. 1 is a block diagram of an image sensor according to an embodiment.

FIG. 2 is a circuit diagram of a pixel according to an embodiment.

FIG. 3 and FIG. 4 are top plan views of an image sensor according to an embodiment.

FIG. 5 is a cross-sectional view of FIG. 3, taken along the line I-I′.

FIG. 6 is a cross-sectional view of FIG. 3, taken along the line II-II′.

FIG. 7 to FIG. 17 are top plan views of image sensors according to some embodiments.

FIG. 18 shows a vehicle including the image sensor according to some embodiments.

### DETAILED DESCRIPTION

Hereinafter, embodiments will be described more fully with reference to the accompanying drawings, in which embodiments of the invention are shown. The invention may be implemented in several different forms and is not limited to the embodiments described herein.

In order to clearly describe the present disclosure, parts without explanation and relationship are omitted, and the same reference sign is used for identical or similar components throughout the specification.

In addition, since the size and thickness of each configuration shown in the drawings are arbitrarily indicated for better understanding and ease of description, the invention is not necessarily limited to the drawings. In the drawings, the thickness of layers, films, panels, regions, etc., are exaggerated for clarity. In addition, in the drawings, the thicknesses of some layers and regions are exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean disposed above or below the target element, and will not necessarily be understood to mean disposed “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

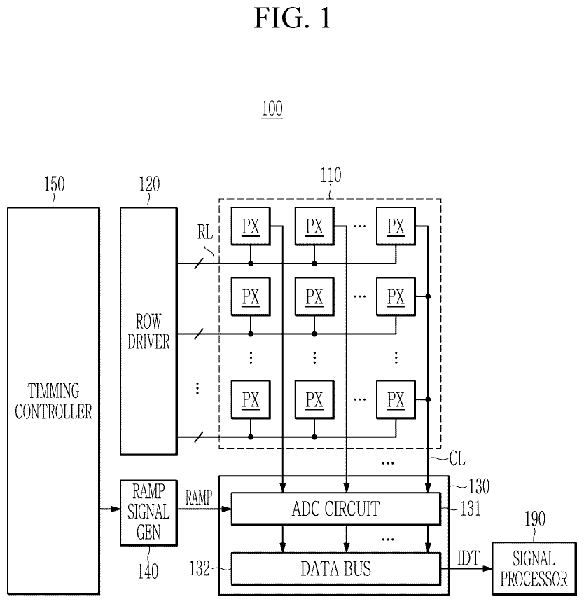

Hereinafter, an image sensor according to an embodiment will be described with reference to FIG. 1 to FIG. 6.

FIG. 1 is a block diagram of an image sensor according to an embodiment.

An image sensor 100 may be mounted on an electronic device with an image or optical sensing function. For example, the image sensor 100 may be mounted on electronic devices such as a camera, a smart phone, a wearable device, an Internet of Things (IoT) device, a home appliance, a tablet personal computer (PC), a personal digital assistant (PDA), a portable multimedia player (PMP), navigation, a drone, and an advanced driver assistance system (ADAS). In addition, the image sensor 100 may be mounted on electronic devices that are included as components in vehicles, furniture, manufacturing facilities, doors, or various measuring devices.

Referring to FIG. 1, the image sensor 100 may include a pixel array 110, a row driver 120, a readout circuit 130, a ramp signal generator 140, a timing controller 150, and a signal processor 190. The readout circuit 130 may include an analog-digital conversion circuit 131 (hereinafter, referred to as an ADC circuit), and a data bus 132.

The pixel array 110 may include a plurality of row lines RL, a plurality of column lines CL, and a plurality of pixels PX. The plurality of pixels PX may be connected with the plurality of row and column lines RL and CL and arranged in a matrix format. Each of the plurality of pixels PX may be an active pixel sensor (APS).

The plurality of pixels PX each may include at least one photoelectric conversion device, and each pixel PX may detect light using a photoelectric conversion device and output an image signal, which is an electrical signal according to the detected light. For example, the photoelectric conversion device is a light sensing element that includes an organic material or an inorganic material, such as an inorganic photo diode, an organic photodiode, a perovskite photodiode, a photo transistor, a photo gate, and a pinned photodiode. In some embodiments, the plurality of pixels PX each may include a plurality of photoelectric conversion devices.

A micro lens for light collection may be placed on top of each of the plurality of pixels PX, or on the top of each pixel group composed of adjacent pixels PX. Each of the plurality of pixels PX may detect light in a specific spectrum region from light received through the micro lens.

For example, a pixel array 110 may include a red pixel for converting light in a red spectrum region into an electric signal, a green pixel for converting light in a green spectrum region into an electric signal, and a blue pixel for converting light in a blue spectrum region into an electric signal.

A color filter may be placed on an upper portion of each of the plurality of pixels PX to transmit light of a specific spectrum region. However, it is not limited to this, and the pixel array 110 may include pixels that convert light of other spectrum regions in addition to red, green, and blue into electric signals.

In some embodiments, the plurality of pixels PX may have a multi-layer structure. A multi-layer structured pixel PX includes a plurality of photoelectric conversion devices that convert light in different spectrum regions into electric signals, and electric signals corresponding to different colors may be generated from the plurality of photoelectric conversion devices. That is, electric signals corresponding to a plurality of colors can be output from one pixel PX.

A color filter array may be placed on the plurality of pixels PX to transmit light of a specific spectrum region, and a color that the pixel can detect can be determined according to the color filter placed on each pixel. However, it is not limited to this, and in some embodiments, in the case of a specific photoelectric conversion device, light of a specific wavelength band may be converted into an electric signal depending on a level of the electric signal applied to the photoelectric conversion device.

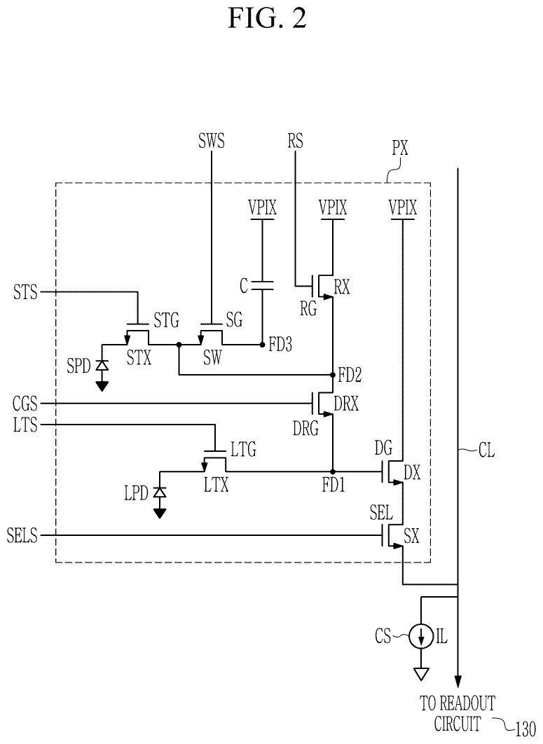

In some embodiments, each of the plurality of pixels PX may include at least two or more photodiodes configured to be exposed to a light source. For example, a pixel PX may include a first photodiode LPD in FIG. 2 and a second photodiode SPD in FIG. 2 with different light receiving areas.

Hereinafter, for better understanding and ease of description, it is assumed that a pixel PX includes the first photodiode LPD and the second photodiode SPD. However, the embodiment is not limited to this, and a pixel PX may include a plurality of photodiodes with the same or different light receiving areas.

In each of the plurality of pixels PX, the charge generated by a photoelectric conversion device such as a photodiode may be accumulated in a floating diffusion node, and the charge accumulated in the floating diffusion node may be converted to a voltage.

Here, the ratio at which the charge accumulated in the floating diffusion node is converted to a voltage may be referred to as a conversion gain. The conversion gain may vary depending on the capacitance of the floating diffusion node.

Specifically, as the capacitance of the floating diffusion node increases, the conversion gain may decrease, and as the capacitance of the floating diffusion node decreases, the conversion gain may increase.

In some embodiments, each of the plurality of pixels PX may operate with a dual conversion gain. The dual conversion gain may include a low conversion gain (LCG) and a high conversion gain (HCG). Since the HCG has a higher conversion rate of charge to voltage, it may be applied to the operation of generating pixel signals corresponding to lower illuminance than the LCG.

Hereinafter, for better understanding and ease of description, an operation mode that generates a pixel signal using a high conversion gain (HCG) is referred to as a high conversion gain (HCG) mode, and an operation mode that generates a pixel signal using a low conversion gain (LCG) is referred to as a low conversion gain (LCG) mode.

In some embodiments, the first photodiode LPD and the second photodiode SPD each may generate pixel signals in the dual conversion gain mode described above.

Specifically, the first photodiode LPD may generate a first pixel signal corresponding to a first illuminance section, which is the lowest illuminance section, by operating in the high conversion gain (HCG) mode, or may generate a second pixel signal corresponding to a second illuminance section, which is a higher illuminance section than the first illuminance section, by operating in the lower conversion gain (LCG) mode.

In addition, the second photodiode SPD operates in the high conversion gain (HCG) mode to generate a third pixel signal corresponding to a third illuminance section, which is a higher illuminance section than the second illuminance section, or operates in the low conversion gain (LCG) mode to generate a fourth pixel signal corresponding to a fourth illuminance section, which is the highest illuminance section. The first pixel signal to fourth pixel signal may be generated within one frame section in which the pixel array 110 is scanned.

The first pixel signal to the fourth pixel signal generated through the dual conversion gain mode of the first photodiode LPD and the second photodiode SPD may be synthesized into one image, and the synthesized image may have a high dynamic range.

Furthermore, when the exposure time of the second photodiode SPD is increased, an image with LED flicker mitigation (LFM) can be implemented. Meanwhile, in order to increase the exposure time of the second photodiode SPD, a high-capacity capacitance that can accumulate a lot of charge can be added. This will be described later in detail with reference to FIG. 2.

In some embodiments, each of the plurality of pixels PX may operate in a single exposure method, performing one exposure, or in a multiple exposure method, performing multiple exposures. For example, a pixel PX may operate in a single exposure method, generating a pixel signal through the first photodiode LPD and/or the second photodiode SPD after one expose operation. As another example, a pixel PX may operate in a multi-exposure method, generating a pixel signal through the first photodiode LPD and/or the second photodiode SPD in response to a first expose operation, and then additionally generating a pixel signal through the first photodiode LPD and/or the second photodiode SPD in response to a second expose operation.

The row driver 120 may drive the pixel array 110 with a row unit. The row driver 120 decodes a row control signal (e.g., address signal) received from a timing controller 150, and selects at least one row line among row lines forming the pixel array 110 in response to the decoded row control signal. For example, the row driver 120 may generate a selection signal for selecting one of a plurality of rows. The pixel array 110 may output a pixel signal from the row selected by the selection signal provided from the row driver 120.

The row driver 120 may transmit control signals for outputting the pixel signal to the pixel array 110, and the pixel PX may output the pixel signal by operating in response to the control signals. For example, the row driver 120 may generate control signals for controlling the first photodiode LPD and the second photodiode SPD to operate in the high conversion gain (HCG) mode or the low conversion gain (LCG) mode during a readout period, and provide the generated control signals to the pixel array 110.

The ramp signal generator 140 may generate a ramp signal RAMP that increases or decreases with a predetermined slope, and provide the ramp signal RAMP to an ADC circuit 131 of the readout circuit 130.

The readout circuit 130 may read out a pixel signal from pixels PX of a row selected by the row driver 120 among the plurality of pixels PX. In this case, the pixel signal may include a reset signal or an image signal (or sensing signal).

The readout circuit 130 may convert the reset signals and the image signals received from the pixel array 110 through the plurality of column lines CL into digital data based on the ramp signal RAMP from the ramp signal generator 140, thereby generating and outputting pixels values respectively corresponding to the plurality of pixels PX as row units.

The ADC circuit 131 may include a plurality of ADCs corresponding to the plurality of column lines CL, and each of the plurality of ADCs compares a reset signal and an image signal received through the corresponding column lines CL with a ramp signal RAMP, respectively, and generates pixel values based on comparison results. For example, the ADC may remove the reset signal from the image signal, and generate a pixel value indicating a detected light amount from the pixel PX.

The plurality of pixel values generated by the ADC circuit 131 may output as image data IDT through the data bus 132. For example, the image data IDT may be provided by an internal or external image signal processor of the image sensor 100.

The data bus 132 may temporarily store the pixel value output from the ADC circuit 131 and then output it. The data bus 132 may include a plurality of column memories and a column decoder. The plurality of pixel values stored in the plurality of column memories may be output as the image data IDT under control of the column decoder.

The ADC circuit 131 may include a plurality of correlated double sampling (CDS) circuits (not shown) and a plurality of counter circuits (not shown). The ADC circuit 131 may convert the pixel signal input from the pixel array 110 into a pixel value, which is a digital signal. Each pixel signal received through the plurality of column lines CL may be converted into a pixel value, which is a digital signal, by the CDS circuit and the counter circuit.

The CDS circuit may compare the pixel signal received through column lines CL with the ramp signal RAMP and output the comparison result. The CDS circuit may output a comparison signal that transitions from a first level (e.g., logic high) to a second level (e.g., logic low) when the level of the ramp signal RAMP and the level of the pixel signal are substantially the same. The point at which the level of the comparison signal transitions may be determined depending on the level of the pixel signal.

The CDS circuit may sample and hold the pixel signal provided from the pixel (PX) according to the correlated double sampling (CDS) method, and may double sample a level of a specific noise (e.g., reset signal) and a level according to an image to generate a comparison signal based on a level corresponding to the difference.

In some embodiments, the CDS circuit may include one or more comparators. The comparator may be implemented as, for example, an operational transconductance amplifier (OTA). The ADC circuit 131 may include a plurality of delta reset sampling (DRS) circuit (not shown). The DRS circuit may sample the provided pixel signal by reading out the image signal first and then reading out the reset signal according to the DRS method.

In some embodiments, the image sensor 100 may further include a bias current controller (not shown) for increasing or decreasing a bias current when the operation mode of the pixel PX is changed (e.g., changed from LCG mode to HCG mode or changed from HCG mode to LCG mode) during the readout period, and a plurality of bias current controller may be connected to the plurality of column lines CL, respectively. For example, the amount of bias current when a pixel PX operates in HCG mode may be less than the current amount of bias current when it operates in LCG mode.

The signal processor 190 may perform noise reduction processing, gain adjustment, waveform normalization processing, interpolation processing, white balance processing, gamma processing, edge emphasis processing, binning, and this like on image data.

In some embodiments, as the pixel array 110 operates in a high conversion gain (HCG) mode of the first photodiode LPD, a low conversion gain (LCG) mode of the first photodiode LPD, a high conversion gain (HCG) mode of the second photodiode SPD, and a low conversion gain (LCG) mode of the second photodiode SPD, the signal processor 190 may receive pixel signals corresponding to the above-described modes from the data bus 132 and merge the received pixel signals to generate an image with a high dynamic range. Meanwhile, in an embodiment, the signal processor 190 may be provided in an external processor of the image sensor 100.

FIG. 2 is a circuit diagram of a pixel according to an embodiment.

Referring to FIG. 2 together with FIG. 1, a pixel PX may include a plurality of photodiodes, for example, a first photodiode LPD and a second photodiode SPD.

The pixel PX may include a capacitor C and a plurality of transistors, for example, a first transmission transistor LTX, a second transmission transistor STX, a reset transistor RX, a driving transistor DX, a selection transistor SX, a gain control transistor DRX (or a conversion gain control transistor), or a switch transistor SW.

Control signals STS, LTS, RS, SELS, CGS, and SWS may be applied to the pixel PX, and at least some of the control signals may be generated in the row driver 120.

The first photodiode LPD and the second photodiode SPD may generate photocharges. The number of the photocharges generated may vary depending on the intensity of light. For example, the first photodiode LPD and the second photodiode SPD may generate charges, that is, electrons with negative charge and holes with positive charge in proportion to the amount of incident light.

The photo charge generated from the first photodiode LPD and the second photodiode SPD may be transmitted and accumulated in at least one of floating diffusion regions FD1, FD2, and FD3. A parasitic capacitor (not shown) may be formed in each of the floating diffusion regions FD1, FD2, and FD3, or a capacitor element may be connected.

The pixel PX may include the first transmission transistor LTX. The first transmission transistor LTX may include a first transmission gate LTG. The first transmission transistor LTX may be connected between the first photodiode LPD and a first floating diffusion region FD1. A first terminal of the first transmission transistor LTX may be connected with an output end of the photodiode LPD, and a second terminal of the first transmission transistor LTX may be connected with the first floating diffusion region FD1.

The first transmission transistor LTX may be turned-on or turned-off in response to a first transmission control signal LTS applied through the first transmission gate LTG from the row driver 120, and may transmit photo charge generated in the first photodiode LPD to the first floating diffusion region FD1.

A pixel PX may include a conversion gain transistor DRX. The conversion gain transistor DRX may include a conversion gain gate DRG. A first terminal of the conversion gain transistor DRX may be connected to the first floating diffusion region FD1, and a second terminal of the conversion gain transistor DRX may be connected to a second floating diffusion region FD2.

The conversion gain transistor DRX may be turned on or turned off in response to a conversion gain signal CGS applied from the row driver 120 through the conversion gain gate DRG, and the first and second floating diffusion regions FD1 and FD2 may be connected to each other.

When the conversion gain transistor DRX is turned on, the first floating diffusion region FD1 and the second floating diffusion region FD2 are connected with each other and thus capacitance may be increased and the conversion gain may be reduced. That is, when the conversion gain transistor DRX is turned on, it may operate in the low conversion gain (LCG) mode. Conversely, when the conversion gain transistor DRX is turned off, it may operate in the high conversion gain (HCG) mode.

The pixel PX may include a second transmission transistor STX. The second transmission transistor STX may include a second transmission gate STG. The second transmission transistor STX may be connected between the second photodiode SPD and the second floating diffusion region FD2. A first terminal of the second transmission transistor STX may be connected with an output end of the second photodiode SPD and a second terminal of the second transmission transistor STX may be connected to the second floating diffusion region FD2.

The second transmission transistor STX may be turned on or turned off in response to a second transmission control signal STS applied from the row driver 120 through the second transmission gate STG, and may transmit the photo charge generated in the second photodiode SPD to the floating diffusion region FD2.

The pixel PX may include a switch transistor SW. The switch transistor SW may include a switch gate SG. A first terminal of the switch transistor SW may be connected to the second floating diffusion region FD2, and a second terminal of the switch transistor SW may be connected to a third floating diffusion region FD3.

The switch transistor SW may be turned on or turned off in response to a switch signal SWS applied from the row driver 120 through the switch gate SG, and may connect the second and third floating diffusion regions FD2 and FD3 to each other.

The pixel PX may include the capacitor C. A first terminal of the capacitor C may be connected to the third floating diffusion region FD3, and a second terminal of the capacitor C may be applied with the pixel voltage VPIX. However, it is not limited to this, and a voltage other than the pixel voltage VPIX may be applied to the second terminal.

When the switch transistor SW is turned on, the second and third floating diffusion regions FD2 and FD3 are connected to each other, and capacitor C may be coupled in parallel with the parasitic capacitor formed in the second floating diffusion region FD2.

Accordingly, the capacitance of the second floating diffusion region FD2 may increase. In other words, the capacitor C may be used to adjust the capacitance of the second floating diffusion region FD2.

In some embodiments, charge may overflow from the second photodiode SPD due to an expose operation, and the overflowed charge may accumulate in the capacitor C through the second floating diffusion region FD2.

The pixel PX may include a reset transistor RX. The reset transistor RX may include a reset gate RG. The reset transistor RX may reset the charge accumulated in at least one of the first to third floating diffusion regions FD1, FD2, and FD3. A reset voltage (e.g., the pixel voltage VPIX) may be applied to the first terminal of the reset transistor RX, and the second terminal of the reset transistor RX may be connected to the second floating diffusion region FD2. However, it is not limited to this, and a voltage other than the pixel voltage VPIX may be applied to the second terminal.

The reset transistor RX may be turned on or turned off in response to a reset control signal RS applied from the row driver 120 through the reset gate RG, and the charges accumulated in the second floating diffusion region FD2 are discharged such that the second floating diffusion region FD2 may be reset.

The pixel PX may include a driving transistor DX. The driving transistor DX may include a driving gate DG. A first terminal of the driving transistor DX may be connected to the selection transistor SX, and a second terminal of the driving transistor DX may be applied with the driving voltage (e.g., pixel voltage VPIX).

The driving transistor DX may operate as a source follower based on a bias current IL generated by a current source CS connected to the column lines CL, and may output a voltage corresponding to the charges accumulated in at least one of the first to third floating diffusion regions FD1, FD2, and FD3 as a pixel signal.

The pixel PX may include a selection transistor SX. The selection transistor SX may include a selection gate SEL. A terminal of the selection transistor SX may be connection to the driving transistor DX, and a second terminal of the selection transistor SX may be connection to the column line CL.

The selection transistor SX may be turned on or turned off in response to a selection signal SELS applied from the row driver 120 through the selection gate SEL. When the selection transistor SX is turned on in the readout operation, a pixel signal including a reset signal corresponding to a reset operation or an image signal corresponding to a charge accumulation operation may be output to the column line CL.

In some embodiments, the first photodiode LPD may generate pixel signals corresponding to a dual conversion gain through the gain control transistor DRX.

Specifically, the gain control transistor DRX is turned on or turned off according to the gain control signal CGS, which transitions to an active level or an inactive level corresponding to a specific conversion gain mode, and thus the first photodiode LPD may generate pixel signals corresponding to the dual conversion gain. For example, when operating in the LCG mode during the readout period of the first photodiode LPD, the gain control signal CGS may have an active level. Therefore, the gain control transistor DRX may be turned on, and the second floating diffusion region FD2 is connected to the first floating diffusion region FD1, thereby increasing the capacitance.

In addition, when operating in the HCG mode during the readout period of the first photodiode LPD, the gain control signal CGS may have an inactive level. Therefore, the gain control transistor DRX may be turned off, and the second floating diffusion region FD2 is not connected to the first floating diffusion region FD1 such that the first floating diffusion region FD1 may maintain the existing capacitance (for example, the capacitance of the parasitic capacitor).

In addition, in some embodiments, the second photodiode SPD may generate pixel signals corresponding to the dual conversion gain through the switch transistor SW.

Specifically, as the switch transistor SW is turned on or turned off according to the switch signal SWS transitioning to an active level or an inactive level corresponding to a specific conversion gain mode, the second photodiode SPD may generate pixel signals corresponding to the dual conversion gain. For example, when operating in the LCG mode during the readout period of the second photodiode SPD, the switch signal SWS may have an active level. Therefore, the switch transistor SW may be turned on, and the third floating diffusion region FD3 is connected to the second floating diffusion region FD2, thereby increasing capacitance.

In addition, when operating in the HCG mode during the readout period of the second photodiode SPD, the switch signal SWS may have an inactive level. Therefore, the switch transistor SW may be turned off, and the third floating diffusion region FD3 is not connected to the second floating diffusion region FD2, and thus the second floating diffusion region FD2 maintains the existing capacitance (for example, the capacitance of the parasitic capacitor).

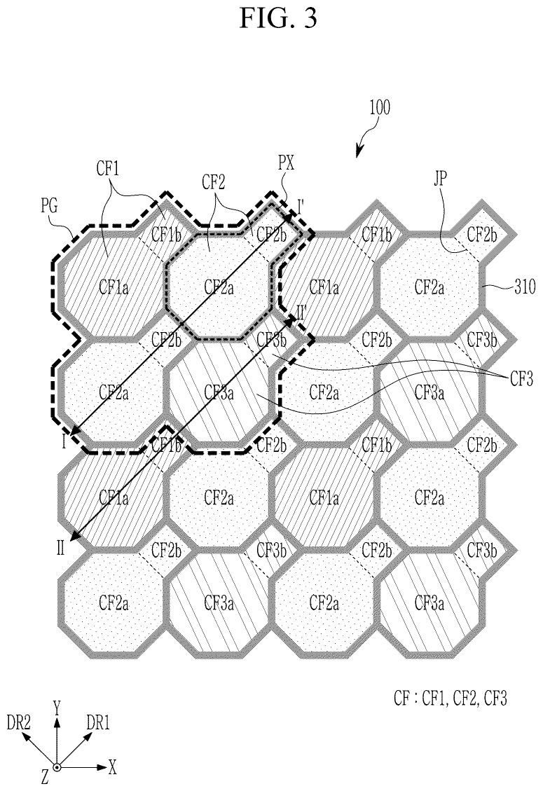

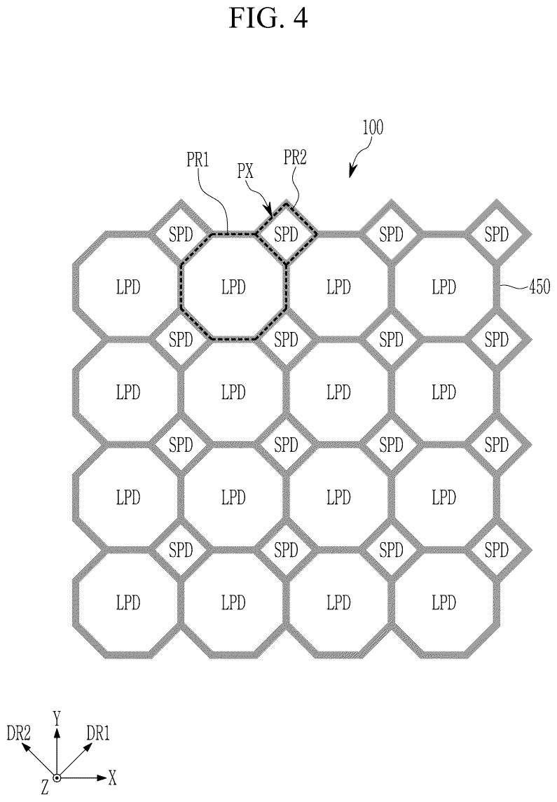

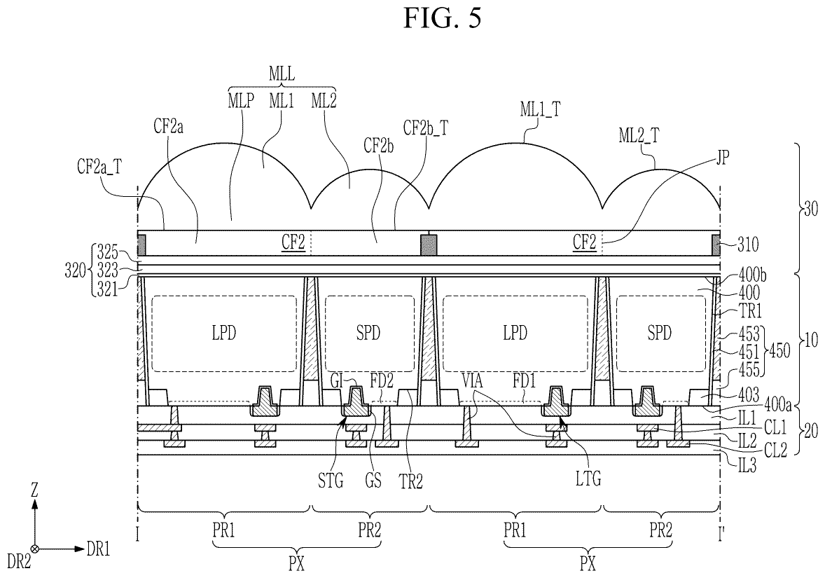

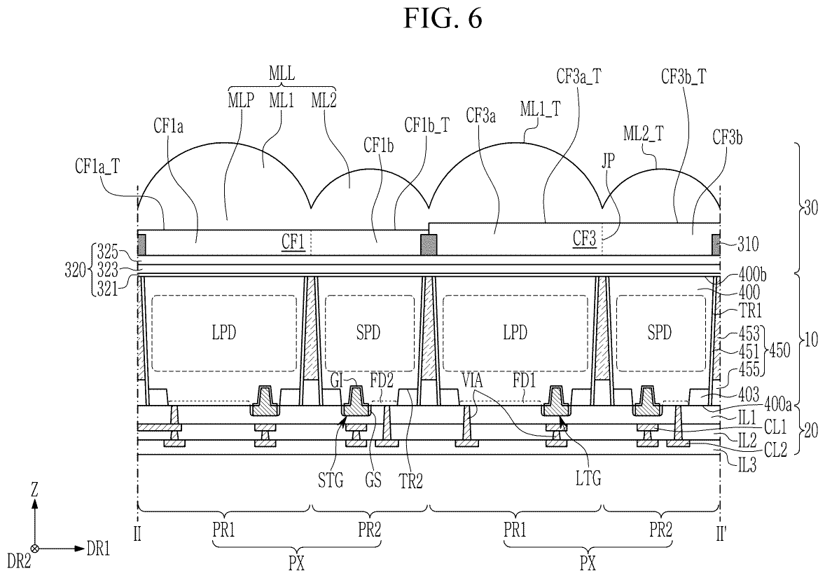

FIG. 3 and FIG. 4 are top plan views of an image sensor according to an embodiment. FIG. 5 is a cross-sectional view of FIG. 3, taken along the line I-I′. FIG. 6 is a cross-sectional view of FIG. 3, taken along the line II-II′.

Specifically, FIG. 3 is a top plan view of a color filter CF and a grid pattern 310 included in the image sensor 100 according to an embodiment, and FIG. 4 is a top plan view of a plurality of diodes LPD and SPD and a pixel isolation pattern 450 included in the image sensor 100 according to an embodiment.

Referring to FIG. 3 to FIG. 6, an image sensor according to an embodiment may include a photoelectric conversion layer 10, a wire region 20, and light transmissive layer 30.

The photoelectric conversion layer 10 may be disposed between the wire region 20 and the light transmissive layer 30. That is, the wire region 20, the photoelectric conversion layer 10, and the light transmissive layer 30 may be sequentially disposed along a third direction Z, which is a vertical direction.

The photoelectric conversion layer 10 may include the substrate 400, a plurality of photodiodes LPD and SPD disposed in the substrate 400, and a pixel isolation pattern 450 disposed between the plurality of photodiodes LPD and SPD. For example, when viewed in a plan view, the pixel isolation pattern 450 may surround each of the plurality of photodiodes LPD and SPD.

The substrate 400 may include a first side 400a and a second side 400b that face each other. The second side 400b of the substrate 400 may be a light-receiving surface on which light is incident. The vertical direction is perpendicular to the second side 400b of the substrate 400.

The wire region 20 may be disposed on the first side 400a of the substrate 400, and the light transmissive layer 30 may be disposed on the second side 400b of the substrate 400. That is, the substrate 400 may be disposed between the wire region 20 and the light transmissive layer 30.

The substrate 400 may be a semiconductor substrate or a silicon on insulator (SOI) substrate. The semiconductor substrate may include, for example, a silicon substrate, a germanium substrate, or a silicon-germanium substrate. The substrate 400 may include impurity of the first conductivity type. For example, the first conductivity type impurity may be a P-type impurity such as aluminum (Al), boron (B), indium (In), and gallium (Ga).

The substrate 400 may include a plurality of pixels PX defined by the pixel isolation pattern 450. The plurality of pixels PX may output a photoelectric signal from incident light coming from the outside.

The plurality of pixels PX may be arranged along rows and columns on a plane. That is, the plurality of pixels PX may be arranged along rows parallel to a first direction X and columns parallel to a second direction Y on a plane. In some embodiments, the first direction X and the second direction Y may be parallel to the second side 400b of the substrate 400, and may be perpendicular to each other.

The plurality of pixels PX may configure a plurality of pixel groups PG. That is, one pixel group PG may include N×M pixels PX in an N×M array. The N and the M each may independently be integers greater than 1.

In an embodiment, each of the plurality of pixel groups PG may include four adjacent pixels PX, each arranged in 2 rows and 2 columns. However, the number and arrangement of pixels PX included in one pixel group are not limited to this and may be changed in various ways.

For example, the plurality of pixel groups PG may each include nine adjacent pixels PX, each arranged in 3 rows and 3 columns. As another example, each of the plurality of pixel groups PG may include 16 adjacent pixel PXs, each arranged in 4 rows and 4 columns.

Each of the plurality of pixels PX is defined by the pixel isolation pattern 450 and may include a first pixel region PR1 and a second pixel region PR2 disposed within the substrate 400.

The pixel isolation pattern 450 may be disposed between the first pixel region PR1 and the second pixel region PR2. The pixel isolation pattern 450 may entirely surround each of the first pixel region PR1 and the second pixel region PR2 on a plane. For example, one first pixel region PR1 and one second pixel region PR2 may constitute one pixel PX. The pixel isolation pattern 450 may surround each of the first pixel region PR1 and the second pixel region PR2 in each pixel PX when viewed in a plan view.

The first pixel region PR1 and the second pixel region PR2 may have different areas. For example, the planar area of the first pixel region PR1 may be larger than the planar area of the second pixel region PR2.

In an embodiment, the first pixel region PR1 may have an octagonal shape on a plane, and the second pixel region PR2 may have a quadrangle shape. The first pixel region PR1 and the second pixel region PR2 may be disposed adjacent to each other. For example, the first pixel region PR1 and the second pixel region PR2 may be disposed side by side along a first diagonal direction DR1 that intersects the first direction X and the second direction Y. That is, the second pixel region PR2 may be disposed adjacent to any one of the sides of the first pixel region PR1.

Each of the plurality of pixels PX may include a first photodiode LPD disposed in the first pixel region PR1 and a second photodiode SPD disposed in the second pixel region PR2. Light incident from the outside may be converted into an electrical signal at each of the photodiodes LPD and SPD.

Since the first photodiode LPD is disposed in the first pixel region PR1 and the second photodiode SPD is disposed in the second pixel region PR2, the area of the first photodiode LPD may be different from the area of the second photodiode SPD. For example, the planar area of the first photodiode LPD may be larger than the planar area of the second photodiode SPD.

As described, a structure in which one pixel PX includes a first photodiode LPD with a relatively wide light receiving area and a second photodiode SPD with a relatively narrow area may be referred to as a split photodiode structure. However, the name of the structure is not limited to this and may be changed in various ways.

Since the first photodiode LPD is larger than the light receiving area of the light receiving area, the first photodiode LPD may generate more charge than the second photodiode SPD under substantially the same light receiving conditions. In other words, the first photodiode LPD may have higher sensitivity than the second photodiode SPD.

Using different planar areas, the first photodiode LPD may generate a pixel signal corresponding to low illuminance, and the second photodiode SPD may generate a pixel signal corresponding to high illuminance.

In addition, the first photodiode LPD may have a shape substantially the same as the first pixel region PR1 on a plane, and the second photodiode SPD may have a shape substantially the same as the second pixel region PR2 on a plane.

For example, the first photodiode LPD may have an octagonal shape on a plane, and the second photodiode SPD may have a quadrangle shape on a plane. However, the planar area and shape of the first photodiode LPD and the second photodiode SPD are not limited to this and may be changed in various ways.

The first and second photodiodes LPD and SPD may be regions doped with second conductivity type impurity. The impurity of the second conductivity type may have a conductivity type opposite to the impurity of the first conductivity type. For example, the second conductivity type impurity may include an N-type impurity such as phosphorus, arsenic, bismuth, and antimony.

The pixel isolation pattern 450 may be disposed within a first trench TR1 that penetrates the substrate 400 in the cross-section. The pixel isolation pattern 450 may be a deep trench isolation (DTI) layer.

The pixel isolation pattern 450 may penetrate the substrate 400. That is, the pixel isolation pattern 450 includes a first side and a second side that face each other, and the first side of the pixel isolation pattern 450 may contact the first side 400a of the substrate 400 and the second side of the pixel isolation pattern 450 may contact the second side 400b of the substrate 400. For example, the first side of the pixel isolation pattern 450 may be coplanar with the first side 400a of the substrate 400, and the second side of the pixel isolation pattern 450 may be coplanar with the second side 400b of the substrate 400.

In FIG. 5 and FIG. 6, it is illustrated that the second side of the pixel isolation pattern 450 and the second side 400b of the substrate 400 are flat. The present disclosure is not limited thereto. In some embodiments, the second side of the pixel isolation pattern 450 and the second side 400b of the substrate 400 may be curved.

In some embodiments, the pixel isolation pattern 450 may be disposed in a trench formed by recessing a part of the substrate 400. That is, the first side of the pixel isolation pattern 450 may be in contact with or may be coplanar with the first side 400a of the substrate 400, and the second side of the pixel isolation pattern 450 may be disposed away from the second side 400b of the substrate 400.

As described, when the second side of the pixel isolation pattern 450 is disposed away from the second side 400b of the substrate 400, the second side of the pixel isolation pattern 450 may have a round shape.

In some embodiments, the pixel isolation pattern 450 may further include a channel stop region (not shown). That is, the pixel isolation pattern 450 may further include a channel stop region disposed between the second side 400b of the substrate 400 and the second side of the pixel isolation pattern 450.

The channel stop region may be doped with a conductivity type different from the photodiodes LPD and SPD. For example, the photodiodes LPD and SPD may be doped with N-type impurity, and the channel stop region may be doped with P-type impurity.

In an embodiment, the pixel isolation pattern 450 may have a shape of which a width decreases as it approaches from the first side 400a of the substrate 400 to the second side 400b on a cross-section. In other words, the pixel isolation pattern 450 may have an inclined side. However, the cross-sectional shape of the pixel isolation pattern 450 is not limited to this and can be changed in various ways.

For example, the pixel isolation pattern 450 may have a shape of which a width increases as it approaches the second side 400b from the first side 400a of the substrate 400 on a cross-section. As another example, the pixel isolation pattern 450 may have a certain width within the substrate 400. That is, a width of the first side of the pixel isolation pattern 450 in contact with the first side 400a of the substrate 400 and a width of the second side of the pixel isolation pattern 450 in contact with the second side 400b of the substrate 400 may be substantially the same.

The pixel isolation pattern 450 may include a first isolation pattern 451, a second isolation pattern 453, and a capping pattern 455.

The first isolation pattern 451 may extend along the inner side of the first trench TR1. The first isolation pattern 451 may include a silicon-based insulating material (e.g., silicon nitride, silicon oxide or silicon oxynitride) or a high dielectric constant material (e.g., hafnium oxide or aluminum oxide). As another example, the first isolation pattern 451 includes a plurality of layers, and each layer may include a different material.

The first isolation pattern 451 may have a lower refractive index than the substrate 400. However, the material included in first isolation pattern 451 is not limited to this and may be changed in various ways.

The second isolation pattern 453 may be disposed on the first isolation pattern 451. Both sides of the second isolation pattern 453 may be surrounded by the first isolation pattern 451. The first isolation pattern 451 may be disposed between the second isolation pattern 45 and the substrate 400. The second isolation pattern 453 may be separated from the substrate 400 by the first isolation pattern 451.

Accordingly, when the image sensor 100 operates, the second isolation pattern 453 may be electrically separated from the substrate 400.

The second isolation pattern 453 includes a crystalline semiconductor material such as polycrystalline silicon, and the second isolation pattern 453 further includes a dopant, and the dopant may include an impurity of the first conductivity type or an impurity of the second conductivity type. As another example, the second isolation pattern 453 may include doped polycrystalline silicon. As another example, the second isolation pattern 453 may include an undoped crystalline semiconductor material. As another example, the second isolation pattern 453 may include undoped polycrystalline silicon. The term “undoped” may mean not undergoing an intentional doping process. The dopant may include N-type dopant or P-type dopant. However, the material included in second isolation pattern 453 is not limited to this and may be changed in various ways.

The capping pattern 455 may be disposed below second isolation pattern 453. The second isolation pattern 453 and the capping pattern 455 are disposed to overlap in the vertical direction, and the capping pattern 455 may be placed adjacent to the first side 400a of the substrate 400.

The capping pattern 455 may include a non-conductive material. The capping pattern 455 may include a silicon-based insulating material (e.g., silicon nitride, silicon oxide or silicon oxynitride) or a high dielectric constant material (e.g., hafnium oxide or aluminum oxide). However, the material included in the capping pattern 455 is not limited to this and can be changed in various ways.

Accordingly, the pixel isolation pattern 450 can prevent photocharges generated by incident light incident on the first pixel region PR1 and the second pixel region PR2 of pixel PX from flowing to the adjacent first and second pixel regions PR1 and PR2 by random drift. In other words, the pixel isolation pattern 450 may prevent or reduce crosstalk between adjacent first and second pixel regions PR1 and PR2.

The photoelectric conversion layer 10 may further include a device isolation pattern 403 disposed within the substrate 400.

The device isolation pattern 403 may be disposed within a second trench TR2 that recesses a portion of the substrate 400. The device isolation pattern 403 is disposed adjacent to the first side 400a of the substrate 400, and may define a region where an active pattern (not shown) is disposed in the first pixel region PR1 and the second pixel region PR2. The device isolation pattern 403 may be disposed away from the photodiodes LPD and SPD. The device isolation pattern 403 may be a shallow trench isolation (STI) layer.

In an embodiment, the device isolation pattern 403 may be penetrated by the pixel isolation pattern 450. In other words, the device isolation pattern 403 may be disposed to surround a part of the side of the pixel isolation pattern 450.

A width of the device isolation pattern 403 may have a shape that decreases as it approaches from the first side 400a of the substrate 400 toward the second side 400b on a cross-section.

In FIG. 5 and FIG. 6, one side of the device isolation pattern 403 is flat with the first side 400a of the substrate 400. The present disclosure is not limited thereto. In some embodiments, one side of the device isolation pattern 403 and the first side 400a of the substrate 400 may be curved.

The device isolation pattern 403 may include an insulating material. In some embodiments, when the device isolation pattern 403 includes the same insulating material as the first isolation pattern 451 and the second isolation pattern 453 of the pixel isolation pattern 450, there may be no boundary between the device isolation pattern 403 and the pixel isolation pattern 450.

The photoelectric conversion layer 10 may further include a first transmission gate LTG and a second transmission gate STG.

The first transmission gate LTG of the first transmission transistor (refer to LTX in FIG. 2) may be disposed in the first pixel region PR1, and the second transmission gate STG of the second transmission transistor (refer to STX in FIG. 2) may be disposed in the second pixel region PR2. The first transmission gate LTG and the second transmission gate STG may be disposed on the first side 400a of the substrate 400.

In an embodiment, each of the first transmission gate LTG and the second transmission gate STG may be a vertical Type. A portion of each of the first transmission gate LTG and the second transmission gate STG is disposed within the substrate 400, and the remaining portion may be protruded onto the first side 400a of the substrate 400.

For example, the first transmission gate LTG and the second transmission gate STG each may include a first portion disposed below the first side 400a of the substrate 400 and a second portion disposed within the substrate 400 and extending from the first side 400a of the substrate 400 toward the second side 400b.

The second portion of each of the first transmission gate LTG and the second transmission gate STG may have a shape of which a width becomes narrower as it approaches from the first side 400a of the substrate 400 toward the second side 400b. However, the shapes of the first transmission gate LTG and second transmission gate STG are not limited to this and may be changed in various ways. For example, the first transmission gate LTG and the second transmission gate STG may each be a planar type.

The gate spacer GS may be disposed on opposite sides of each of the first transmission gate LTG and the second transmission gate STG, which are extended on the first side 400a of the substrate 400. The gate spacer GS may include, for example, silicon nitride, silicon carbonization nitride, or silicon oxynitride.

A gate dielectric layer GI may be disposed between the first transmission gate LTG and the substrate 400 and between the second transmission gate STG and the substrate 400. The gate dielectric layer GI may include the same insulating material as the gate spacer GS. In an embodiment, the gate spacer GS may be disposed between a first insulation layer IL1 and a side surface of the first portion of each of the first transmission gate LTG and the second transmission gate STG, and the gate dielectric layer GI may be disposed between the substrate 400 and the second portion of each of the first transmission gate LTG and the second transmission gate STG.

Although it is not illustrated in FIG. 5 and FIG. 6, at least one of the reset gate RG of the reset transistor RX, the driving gate DG of the driving transistor DX, the selection gate SEL of the selection transistor SX, the conversion gain gate DRG of the conversion gain control transistor DRX, and the switch gate SG of the switch transistor SW as described inf FIG. 2 may be disposed on the first side 400a of substrate 400 in either the first pixel region PR1 or the second pixel region PR2 of the substrate 400.

The photoelectric conversion layer 10 may further include first and second floating diffusion regions FD1 and FD2 disposed within the substrate 400.

The first floating diffusion region FD1 may be disposed within the substrate 400 in the first pixel region PR1, and the second floating diffusion region FD2 may be disposed within the substrate 400 in the second pixel region PR2.

The charges generated from the first photodiode LPD may be transferred to the first floating diffusion region FD1, and the charges generated from the second photodiode SPD may be transferred to the second floating diffusion region FD2. The first and second floating diffusion regions FD1 and FD2 may maintain the charges transferred from the first and second photodiodes LTD and SPD, respectively.

The first floating diffusion region FD1 and the second floating diffusion region FD2 may be disposed adjacent to the first side 400a of the substrate 400. The first floating diffusion region FD1 and the second floating diffusion region FD2 may be disposed by being buried in a region adjacent to the first side 400a of the substrate 400.

The first floating diffusion region FD1 may be disposed between the first transmission transistor LTX and the device isolation pattern 403, and the second floating diffusion region FD2 may be disposed between the second transmission transistor STX and the device isolation pattern 403.

Although it is illustrated in FIG. 5 and FIG. 6 that the first floating diffusion region FD1 does not overlap the first transmission transistor LTX and the second floating diffusion region FD2 does not overlap the second transmission transistor STX, this is not restrictive, and a part of the first floating diffusion region FD1 may be disposed to overlap the first transmission transistor LTX and a part of the second floating diffusion region FD2 may be disposed to overlap the second transmission transistor STX. In an embodiment, the first portion of the second transmission gate STG may overlap the second floating diffusion region FD2 when viewed in a plan view, and the first portion of the first transmission gate LTG may overlap the first floating diffusion region FD1 when viewed in a plan view.

The first floating diffusion region FD1 and the second floating diffusion region FD2 may be doped with impurity of the second conductivity type. For example, the impurity of the second conductivity type may be an N-type impurity.

The first wire region 20 may be disposed on the first side 400a of the substrate 400, and may include a plurality of insulation layers IL1, IL2, and IL3, a plurality of wire layers CL1 and CL2, and a via VIA.

The first wire region 20 may include the first insulation layer IL1, a second insulation layer IL2, and a third insulation layer IL3.

The first insulation layer IL1, the second insulation layer IL2, and the third insulation layer IL3 may be sequentially stacked on the first side 400a of the substrate 400. The number of insulation layers included in the first wire region 20 is illustrative, is not limited to this, and may be changed in various ways.

The first insulation layer IL1 may cover the first side 400a of the substrate 400. The first insulation layer IL1 may cover the first transmission gate LTG and the second transmission gate STG. The second insulation layer IL2 may be disposed on the first insulation layer IL1. The third insulation layer IL3 may be disposed on the second insulation layer IL2.

The first to third insulation layers IL1, IL2, and IL3 may contain insulating material. For example, the first to third insulation layers IL1, IL2, and IL3 may include silicon-based insulating materials such as silicon oxide, silicon nitride, or silicon oxynitride.

The first wire region 20 may include a first wire layer CL1 and a second wire layer CL2. The first wire layer CL1 may be disposed within the second insulation layer IL2. The second wire layer CL2 may be disposed within the third insulation layer IL3. The number of connection wires included in the first wire region 20 is illustrative, is not limited to this, and may be changed in various ways.

A plurality of vias VIA may be disposed within the first insulation layer IL1, the second insulation layer IL2, and the third insulation layer IL3. The first floating diffusion region FD1 and the second floating diffusion region FD2 may be connected to the first wire layer CL1 and/or the second wire layer CL2 through the via VIA. For example, the first floating diffusion region FD1 and the second floating diffusion region FD2 may be connected to the second connection wire CL2 through the via VIA.

Although it is not illustrated in FIG. 5 and FIG. 6, the first transmission gate LTG and the second transmission gate STG may be connected to the first wire layer CL1 and/or the second wire layer CL2 through the via VIA.

The first wire layer CL1, the second wire layer CL2, and the via VIA may contain a metal material. For example, the first wire layer CL1, the second wire layer CL2, and the via VIA may contain copper (Cu).

The light transmissive layer 30 may be disposed on the second side 400b of the substrate 400.

The light transmissive layer 30 may include an insulating structure 320, a color filter CF, a grid pattern 310, and a micro lens layer MLL.

The light transmissive layer 30 may collect and filter light incident from the outside and provide the light to first and second photodiodes LPD and SPD.

The insulating structure 320 may cover the entirety of the second side 400b of the substrate 400. The insulating structure 320 may be disposed between the second side 400b of the substrate 400 and the color filter CF and between the second side 400b of the substrate 400 and the grid pattern 310.

The insulating structure 320 may prevent reflection of light such that the light incident on the second side 400b of the substrate 400 can reach the first and second photodiodes LPD and SPD. The insulating structure 320 may be referred to as an anti-reflection structure.

The insulating structure 320 may include a first fixed charge layer 321, a second fixed charge layer 323, and a planarization layer 325 sequentially stacked on the second side 400b of the substrate 400.

The first and second fixed charge layers 321 and 323 may include a metal oxide layer or a metal fluoride layer containing an amount of oxygen or fluorine less than the stoichiometric ratio. Accordingly, the first and second fixed charge layers 321 and 323 may have a negative fixed charge.

The first and second fixed charge layers 321 and 323 may include oxide (metal oxide) or metal fluoride (metal fluoride) containing at least one metal among hafnium (Hf), zirconium (Zr), aluminum (Al), tantalum (Ta), titanium (Ti), yttrium, and lanthanoid.

Each of the first fixed charge layer 321, the second fixed charge layer 323, and the planarization layer 325 may include a different material. The first fixed charge layer 321 may include at least one of aluminum oxide, tantalum oxide, titanium oxide, and hafnium oxide.

The second fixed charge layer 323 may include another one of aluminum oxide, tantalum oxide, titanium oxide, and hafnium oxide. For example, the first fixed charge layer 321 may include titanium oxide, the second fixed charge layer 323 may include hafnium oxide, and the planarization layer 325 may include silicon oxide.

Hole accumulation may occur around the fixed charge layer. For example, holes generated from the first and second photodiodes LPD and SPD may be fixed and accumulated at the fixed charge layer. Accordingly, the occurrence of dark currents and white spots can be effectively reduced.

Although it is not illustrated in FIG. 5 and FIG. 6, in some embodiments, a silicon anti-reflection layer (not shown) may further be disposed between the second fixed charge layer 323 and the planarization layer 325. The anti-reflection layer may prevent light reflection such that the light incident on the second side 400b of the substrate 400 can reach the first and second photodiodes LPD and SPD. For example, the anti-reflection layer may include metal oxide (e.g., aluminum oxide or hafnium oxide) or silicon-based insulating material (e.g., silicon oxide or silicon nitride).

The color filter CF may be disposed on the second side 400b of the substrate 400.

The image sensor 100 according to an embodiment may include a plurality of color filters CF. The plurality of color filters CF may be disposed to respectively correspond to the plurality of pixels PX.

The plurality of color filters CF may include a first color filter CF1, a second color filter CF2, and a third color filter CF3 having different colors. For example, the color filters CF may selectively filter the incident light into different colors. The plurality of color filters CF may include primary color filters. For example, the first color filter CF1 may be a red color filter filtering the incident light into a red color component, the second color filter CF2 may be a green color filter filtering the incident light into a green color component, and the third color filter CF3 may be a blue color filter filtering the incident light into a blue color component.

In some embodiments, the plurality of color filters CF may include complementary color filters. For example, the first color filter CF1 may be a cyan filter filtering the incident light into a cyan light, the second color filter CF2 may be a magenta filter filtering the incident light into a magenta light, and the third color filter CF3 may be a yellow filter filtering the incident light into a yellow light.

In an embodiment, the plurality of color filters CF may have a Bayer pattern on a plane. That is, the color filters CF may have patterns in which the number of second color filter CF2 is about twice as large as the number of first color filter CF1 or third color filter CF3.

For example, in one pixel group PG, the color filters CF respectively disposed above the plurality of pixels PX arranged in 2 rows and 2 columns on the plane may include two second color filters CF2 that are arranged diagonally and the first color filter CF1 and third color filter CF3 that are arranged diagonally.

For example, the two second color filters CF2 are disposed adjacent to each other in a first diagonal direction DR1, which intersects the first direction X and second direction Y, and first color filter CF1 and third color filter CF3 are disposed adjacent to each other in a second diagonal direction DR2, which intersects the first direction X, the second direction Y, and the first diagonal direction DR1. The ratio of the first color filter CF1, the second color filter CF2, and the third color filter CF in planar area when viewed in a plan view may be about 1:2:1.

Each of first color filter CF1 and third color filter CF3 may be disposed between two adjacent second color filters CF2. The color filters CF may be repeatedly arranged along the first direction X and the second direction Y in the Bayer pattern. However, the planar arrangement of the color filters CF is not limited to this and can be changed in various ways.

The first and second pixel regions PR1 and PR2 of each of the plurality of pixels PX may share one color filter CF. In other words, a first photodiode LPD disposed in the first pixel region PR1 and a second photodiode SPD disposed in the second pixel region PR2 may share one color filter CF.

The color filter CF covers the entirety of the first pixel region PR1 and the entirety of the second pixel region PR2 in one pixel PX, and may be disposed continuously in the first pixel region PR1 and the second pixel region PR2.

Accordingly, the first and second photodiodes LPD and SPD of one pixel PX may convert light passing through a single color filter CF (i.e., the same color filter) into an electrical signal.

Specifically, the first to third color filters CF1, CF2, and CF3 may include first portions CF1a, CF2a, and CF3a disposed to correspond to the first photodiode LPD disposed in the first pixel region PR1, and second portions CF1b, CF2b, and CF3b disposed to correspond to the second photodiode SPD disposed in the second pixel region PR2.

The first portions CF1a, CF2a, and CF3a of the first to third color filters CF1, CF2, and CF3 may have substantially the same shape as the first photodiode LPD on a plane, and the second portions CF1b, CF2b, and CF3b may have substantially the same shape as the second photodiode SPD on a plane. That is, the first portions CF1a, CF2a, and CF3a of the first to third color filters CF1, CF2, and CF3 may have an octagonal shape on a plane, and the second portions CF1b, CF2b, and CF3b may have a quadrangle shape on a plane.

In addition, the areas of first portions CF1a, CF2a, and CF3a of the first to third color filters CF1, CF2, and CF3 may respectively be larger than the areas of the second portions CF1b, CF2b, and CF3b.

In the first to third color filters CF1, CF2, and CF3, respectively, the first portions CF1a, CF2a, and CF3a and the second portions CF1b, CF2b, and CF3b may be disposed adjacent to the first diagonal direction DR1.

The grid pattern 310 may be disposed on the pixel isolation pattern 450. The grid pattern 310 may be disposed to overlap at least a part of the pixel isolation pattern 450 in the third direction Z, which is a thickness direction parallel to the vertical direction.

Although it is illustrated in FIG. 5 and FIG. 6 that the grid pattern 310 completely overlaps the isolation pattern 450 in the third direction Z, which is the thickness direction, the arrangement between the grid pattern 310 and the pixel isolation pattern 450 is not limited to this and can be changed in various ways.

For example, the grid pattern 310 may be disposed to overlap a part of the pixel isolation pattern 450 in the third direction Z. That is, the grid pattern 310 and the color filters CF1, CF2, and CF2 may be disposed by shifting from the center of the photodiodes LPD and SPD.

A center of the grid pattern 310 and a center of color filters CF1, CF2, and CF3 may be shifted toward the first direction X from the center of the photodiodes LPD and SPD when viewed in a plan view. As another example, the grid pattern 310 may be shifted such that it does not overlap with the pixel isolation pattern 450 when viewed in a plan view.

As described, the degree to which the grid pattern 310 and the color filters CF1, CF2, and CF3 are shifted from the center of the photodiodes LPD and SPD may increase as a distance from the center of the substrate 400 increases, that is, as it goes toward the outer portion of the substrate 400.

Since light enters at an oblique angle in regions other than the center of the substrate 400, the light entering at an oblique angle can be corrected to place at the center of first pixel region PR1 and the second pixel region PR2, respectively.

In an embodiment, the planar arrangement shape of the grid pattern 310 may be different from the planar arrangement shape of the pixel isolation pattern 450 disposed between the photodiodes LPD and SPD.

In an embodiment, the planar shape of the grid pattern 310 may be substantially the same as the planar shape of the pixel isolation pattern 450 extending along an edge of one pixel PX.

The grid pattern 310 is disposed on at least a part of the pixel isolation pattern 450 surrounding the first photodiode LPD and the pixel isolation pattern 450 surrounding the second photodiode SPD, and the grid pattern 310 may not be disposed on the pixel isolation pattern 450 disposed at a boundary between the first photodiode LPD and the second photodiode SPD in the same pixel.

In other words, the grid pattern 310 may be disposed so as not to overlap with the pixel isolation pattern 450 disposed between the first photodiode LPD and the second photodiode SPD in the same pixel.

As the grid pattern 310 is disposed to surround one pixel PX, the grid pattern 310 may be located at a boundary between a first photodiode LPD of any one of the plurality of pixels PX and a first photodiode LPD of another pixel PX and a boundary between a first photodiode LPD of any one of the plurality of pixels PX and a second photodiode SPD of another pixel PX.

The plurality of color filters CF may be formed within a region defined by the grid pattern 310 on the insulating structure 320.

In an embodiment, the grid pattern 310 has a lattice structure on a plane and may be disposed between the plurality of color filters CF. The grid pattern 310 may entirely surround the color filter CF disposed to correspond to one pixel PX. In other words, the color filter CF disposed to correspond to one pixel PX may entirely cover the first photodiode LPD, the second photodiode SPD, and the pixel isolation pattern 450 disposed between the first photodiode LPD and the second photodiode SPD.

The grid pattern 310 may extend along at least some of side surfaces of the first portions CF1a, CF2a, and CF3a and at least some of side surfaces of the second portions CF1b, CF2b, and CF3b included in the plurality of color filters CF.

The grid pattern 310 may be disposed between the plurality of color filters CF with different colors.

Specifically, the grid pattern 310 is disposed adjacent to each other and is disposed between the first portions CF1a, CF2a, and CF3a of one of the plurality of color filters CF having different colors and the first portions CF1a, CF2a, and CF3a of another one of the plurality of color filters CF.

The grid pattern 310 may be disposed adjacent to each other, and may be disposed between the first portions CF1a, CF2a, and CF3a of one of the plurality of color filters CF having different colors and the second portions CF1b, CF2b, and CF3b of another one of the plurality of color filters CF.

In addition, the grid pattern 310 is disposed adjacent to each other, and may be disposed between the first portions CF1a, CF2a, and CF3a of one of the plurality of color filters CF having the same color and the second portions CF1b, CF2b, and CF3b of another one of the plurality of color filters CF. For example, the grid pattern 310 may be disposed between the first portion CF2a of one of the plurality of second color filter CF2s and the second portion CF2b of another second color filter CF.

An upper surface and opposite sides of the grid pattern 310 may be covered by the plurality of color filters CF adjacent to each other. A portion of the upper surface and one side of the grid pattern 310 may be covered with one of the plurality of color filters CF, and the remaining portion of the upper surface and the other side may be covered with another one of the plurality of color filters CF. Any one of the plurality of color filters CF adjacent to each other and another one of the plurality of color filters CF may contact each other on the grid pattern 310. For example, upper parts of two adjacent color filters may contact each other and lower parts thereof may contact opposite side surfaces of a portion of the grid pattern 310, respectively.

For example, a part of the upper surface and one side of the grid pattern 310 are covered with the first color filter CF1, the remaining part of the upper surface and the other side are covered with the third color filter CF3, and the first color filter CF1 and the third color filter CF3 may contact each other on the grid pattern 310. As another example, a part of the upper surface and one side of the grid pattern 310 are covered with one of the plurality of second color filter CF2, the remaining part of the upper surface and the other side are covered with another one of the plurality of second color filter CF2, and the plurality of second color filters CF2 adjacent to each other may contact each other on the grid pattern 310.

The grid pattern 310 may not be disposed between the first portions CF1a, CF2a, and CF3a and the second portions CF1b, CF2b, and CF3b included in the plurality of color filters CF. For example, the grid pattern 310 may not be disposed between the first portion CF1a and the second portion CF2b of the first color filter CF1, between the first portion CF2a and the second portion CF2b of the second color filter CF2, and the first portion CF3a and the second portion CF3B of the third color filter CF3.

Accordingly, the side surfaces of the first portions CF1a, CF2a, and CF3a included in the plurality of color filters CF may directly contact the side surfaces of the second portions CF1b, CF2b, and CF3b. The first portions CF1a, CF2a, and CF3a and the second portions CF1b, CF2b, and CF3b included in the plurality of color filters CF are integrated with each other, and there may be no boundary between them.

The grid pattern 310 may be disposed on both sides of a junction portion JP where the first portions CF1a, CF2a, and CF3a and the second portions CF1b, CF2b, and CF3b included in the plurality of color filters CF are in contact with each other.

That is, the grid pattern 310 may be disposed apart from each other in the second diagonal direction DR2, while disposing the junction portion JP where the first portions CF1a, CF2a, and CF3a and the second portions CF1b, CF2b, and CF3b included in each of the plurality of color filters CF are in contact with each other. That is, the junction portion JP where the first portions CF1a, CF2a, and CF3a and the second portions CF1b, CF2b, and CF3b included in the plurality of color filters CF are in contact with each other and extend from the grid pattern 310 disposed one side in the second diagonal direction DR2 toward the grid pattern 310 disposed on the other side of the second diagonal direction DR2.

In addition, the junction portion JP where the first portions CF1a, CF2a, and CF3a and the second portions CF1b, CF2b, and CF3b included in the plurality of color filters CF are in contact with each other is disposed between the grid patterns 310 that are spaced apart from each other, and thus the junction portion JP may not overlap the grid pattern 310 in the third direction Z, which is the thickness direction.

In an embodiment, the first portions CF1a, CF2a, and CF3a and the second portions CF1b, CF2b, and CF3b included in the plurality of color filters CF may have substantially the same thickness. That is, the side surfaces of the first portions CF1a, CF2a, and CF3a and the side surfaces of the second portions CF1b, CF2b, and CF3b included in the plurality of color filters CF may fully contact each other.

Specifically, a top surface CF1a_T of the first portion CF1a and a top surface CF1b_T of the second portion CF1b of the first color filter CF1 may be disposed substantially on the same level in the third direction Z, a top surface CF2a_T of the first portion CF2a and a top surface CF2b_T of the second portion CF2b of the second color filter CF2 may be disposed substantially on the same level in the third direction Z, and a top surface CF3a_T of the first portion CF3a and a top surface CF3b_T of the second portion CF3b of the third color filter CF3 may be disposed substantially on the same level in the third direction Z.

A thickness of each of the first portions CF1a, CF2a, and CF3a and a thickness of each of the second portions CF1b, CF2b, and CF3b included in each of the plurality of color filters CF may be substantially the same.

That is, the junction portions JP where the first portions CF1a, CF2a, and CF3a and the second portions CF1b, CF2b, and CF3b included in the plurality of color filters CF are in contact with each other may have thicknesses corresponding to the first portions CF1a, CF2a, and CF3a and/or second portions CF1b, CF2b, and CF3b included in the plurality of color filters CF.

Here, “same” and “corresponding” may mean not only being completely the same but also including fine differences that may occur due to margins in the process and the like.

In other words, at the process stage of forming the plurality of color filters CF, when a fine thickness difference occurs between the first portions CF1a, CF2a, and CF3a and the second portions CF1b, CF2b, and CF3b included in each plurality of color filters CF due to process margin and the like, the junctions where the first portions CF1a, CF2a, and CF3a and the second portions CF1b, CF2b, and CF3b included in each of the plurality of color filters CF contact each other may have thicknesses corresponding to thicknesses of the first portions CF1a, CF2a, and CF3a or thicknesses of the second portions CF1b, CF2b, and CF3b that are in contact with the first portions CF1a, CF2a, and CF3a.

In addition, as side surfaces of the first portions CF1a, CF2a, and CF3a and side surfaces of the second portions CF1b, CF2b, and CF3b included in each of the plurality of color filters CF are entirely in contact with each other, thicknesses of junction portions JP where the side surfaces of the first portions CF1a, CF2a, and CF3a included in each of the plurality of color filters CF and the second portions CF1b, CF2b, and CF3b contact each other may be substantially the same as the thickness of the grid pattern 310, or may be greater than the thickness of the grid pattern 310.

In an embodiment, thicknesses of color filters having different colors among the plurality of color filters CF may be different from each other. In an embodiment, at least one of the thickness of the first color filter CF1, the thickness of the second color filter CF2, and the thickness of the third color filter CF3 may be different.

For example, the thickness of the first color filter CF1 may be different from the thickness of the third color filter CF3. As another example, the thickness of the second color filter CF2 may be different from the thicknesses of the first color filter CF1 and the third color filter CF3. However, it is not limited to this, and the thickness of the first color filter CF1, the thickness of the second color filter CF2, and the thickness of the third color filter CF3 may be substantially the same.

In an embodiment, the grid pattern 310 may include at least one of metal material, metal nitride, and a material having a refractive index smaller than a refractive index of the color filter CF. For example, the grid pattern 310 may include at least one of organic materials such as titanium nitride (TiN), tungsten (W), aluminum (Al), copper (Cu), and a polymer layer containing silica nano particles. However, the material included in the grid pattern 310 is not limited to this and can be changed in various ways.

Although it is illustrated in FIG. 5 and FIG. 6 that the grid pattern 310 includes of a single layer, the number of layers included in the grid pattern 310 is not limited to this and can be changed in various ways. For example, the grid pattern 310 includes a plurality of layers, and each of the plurality of layers may include at least one of the above-described materials.

A micro lens layer MLL may be disposed on the color filters CF1, CF2, and CF3 which are disposed on the second side 400b of the substrate 400. In other words, the micro lens layer MLL may be disposed on the second side 400b of the substrate 400, which is the light-receiving surface.

The micro lens layer MLL may include a flat portion MLP disposed on the color filters CF1, CF2, and CF3, and a first micro lens ML1 and a second micro lens ML2 disposed on the flat portion MLP.

The first micro lens ML1, the second micro lens ML2, and the flat portion MLP include the same material (e.g., a light-transmissive material) and may be integrally formed. That is, there may be no boundary between the first micro lens ML1, the second micro lens ML2, and the flat portion MLP.

The flat portion MLP of the micro lens layer MLL may entirely cover the color filters CF1, CF2, and CF3. That is, the flat portion MLP may be disposed in the first pixel region PR1 and the second pixel region PR2.

As the flat portion MLP is disposed on the color filters CF1, CF2, and CF3, even if the color filters CF1, CF2, and CF3 have different thicknesses, the flat portion MLP may cover upper regions of the color filters CF1, CF2, and CF3 to provide a planarized surface which corresponds to an upper surface of the flat portion MLP. The first and second micro lenses ML1 and ML2 may be formed on the planarized surface of the flat portion MLP.

In an embodiment, the micro lens layer MLL may include a plurality of first micro lenses ML1 and a plurality of second micro lenses ML2 with a predetermined curvature radius. Each of the plurality of first micro lenses ML1 may be disposed in the first pixel region PR1, and each of the plurality of second micro lenses ML2 may be disposed in the second pixel region PR2.

Each of the plurality of first micro lenses ML1 may be disposed to overlap with the first portions CF1a, CF2a, and CF3a of the first photodiode LPD and the color filters CF, respectively, disposed in the first pixel region PR1. For example, each of the plurality of first micro lenses ML1 may overlap the first photodiode LPD of a corresponding pixel and a corresponding first portion of the first portions CF1a, CF2a, and CF3a of the corresponding pixel. The first photodiode LPD and the corresponding first portion may be disposed in the first pixel region PR1.

Each of the plurality of second micro lenses ML2 may be disposed to overlap with the second portions CF1b, CF2b, and CF3b of the second photodiode SPD and the color filters CF, respectively, disposed in the second pixel region PR2. For example, each of the plurality of second micro lenses ML2 may overlap the second photodiode SPD of a corresponding pixel and a corresponding second portion of the second portions CF1b, CF2b, and CF3b. The second photodiode SPD and the corresponding second portion may be disposed in the second pixel region PR2.

Since the planar area of the first photodiode LPD disposed in the first pixel region PR1 is larger than the planar area of the second photodiode SPD disposed in the second pixel region PR2, the planar area of the first micro lens ML1 may be larger than the planar area of the second micro lens ML2. In an embodiment, a width, in the first diagonal direction DR1, of the first micro lens ML1 may be larger than a width, in the first diagonal direction DR1, of the second micro lens ML2. In response to a difference in area between the first photodiode LPD and the second photodiode SPD, the curvature radius of the first micro lens ML1 may be larger than the curvature radius of the second micro lens ML2.

In addition, the thickness of the first micro lens ML1 may be different from the thickness of the second micro lens ML2. For example, the thickness of the first micro lens ML1 may be greater than the thickness of the second micro lens ML2. Here, the thickness may mean the thickness of the thickest part of the first micro lens ML1 and the second micro lens ML2.

Accordingly, an upper surface ML1_T of the first micro lens ML1 can be disposed at a higher level than an upper surface ML2_T of the second micro lens ML2. Here, the upper surface ML1_T of the first micro lens ML1 and the upper surface ML2_T of the second micro lens ML2 may each mean the upper surface of the thickest part of the first micro lens ML1 and the second micro lens ML2. In an embodiment, the uppermost surface of the upper surface ML1_T of the first micro lens ML1 may be higher than the uppermost surface of the upper surface of ML2_T of the second micro lens ML2. However, the relationships of the area, thickness, and curvature radius of the first and second micro lenses ML1 and ML2 are not limited to this and may be changed in various ways.

However, unlike shown in FIG. 5 and FIG. 6, in some embodiments, the first micro lens ML1 and the second micro lens ML2 may each be disposed with a shift from the center of the first photodiode LPD and the center of the second photodiode SPD in the first direction X.

The degree to which the first micro lens ML1 and the second micro lens ML2 are each shifted from the center of the first photodiode LPD and the center of the second photodiode SPD may increase as they move away from the center of the substrate 400, that is, toward the outer edge of the substrate 400. For example, the shift amount of the first micro lens ML1 in the outer edge of the substrate 400 may be greater than the shift amount of the first micro lens ML1 in a region adjacent to the center of the substrate 400.

In addition, when the first and second micro lenses ML1 and ML2 are shifted from the center of the photodiodes LPD and SPD, the first and second micro lenses ML1 and ML2 may be further shifted toward the first direction X than the grid pattern 310 and the color filters CF1, CF2, and CF3 described above.

This is to correct light entering at an oblique angle in regions other than the center of the substrate 400 to be disposed at the center of first pixel region PR1 and second pixel region PR2, respectively. For example, the first and second micro lenses ML1 and ML2 may be further shifted from the centers of the photodiodes LPD and SPD, respectively, compared to the shift of the grid pattern 310 and the color filters CF1, CF2, and CF3 as described above to compensate for light entering at oblique angles, thereby the light being directed toward the centers of the first and second pixel regions PR1 and PR2, even in areas away from the center of the substrate 400.

The overlap relationship between the above-mentioned photodiodes LPD and SPD, color filters CF1, CF2, and CF3, and micro lenses ML1, and ML2 may mean not only an overlap relationship according to the third direction Z, but also an overlap relationship according to the traveling direction of light incident on photodiodes LPD and SPD.

That is, the photodiodes LPD and SPD, the color filters CF1, CF2, and CF3, and the micro lenses ML1 and ML2 can be disposed to overlap along the traveling path direction of light incident on the photodiodes LPD and SPD from the outside.

For example, as the centers of photodiodes LPD and SPD, the centers of the color filters CF1, CF2, and CF3, and the centers of the micro lenses ML1 and ML2 are staggered, the centers of the photodiodes LPD and SPD, the centers of the color filters CF1, CF2, and CF3, and the centers of the micro lenses ML1 and ML2 can be disposed along an extension of the path of light incident on the photodiodes LPD and SPD.

In the image sensor 100 according to an embodiment, as the grid pattern 310 is not disposed at the boundary between the photodiodes LPD and SPD having different areas in the same pixel, and thus the second photodiode SPD, which has a relatively narrow light receiving area, minimizes the amount of light lost by the grid pattern 310, thereby improving the sensitivity of the second photodiode SPD.

In addition, since the grid pattern 310 is not disposed at the boundary between the first photodiodes LPD and SPD, a color filter CF with a substantially uniform thickness can be formed over the photodiodes LPD and SPD, and thus it is possible to prevent the spectral characteristics of the light incident through the color filter CF on the first photodiode LPD and the second photodiode SPD each having a different area in the same pixel can be prevented.

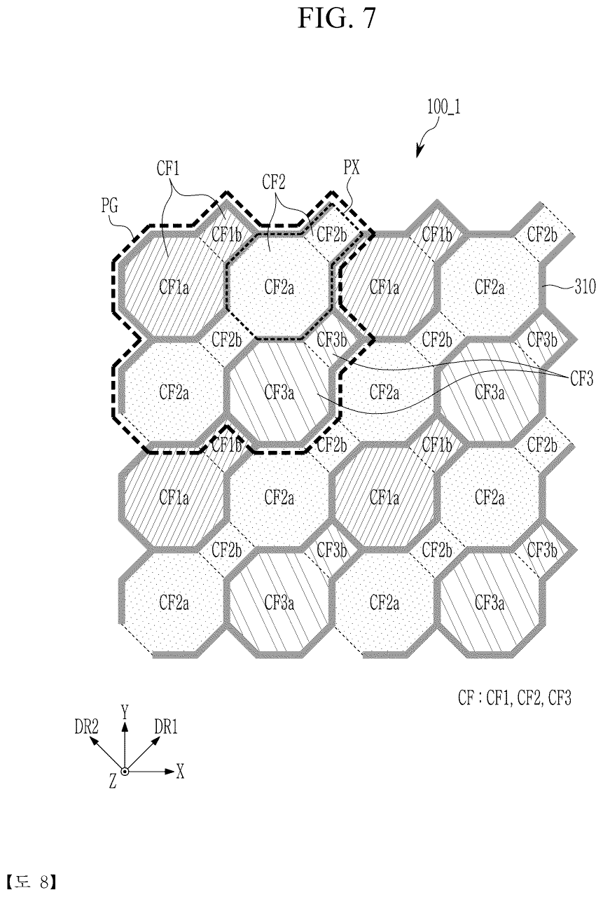

Hereinafter, referring to FIG. 7 to FIG. 17, image sensors according to various embodiments will be described. In the following embodiments, the same components as the previously described embodiments will be referred to by the same reference numerals, redundant descriptions will be omitted or simplified, and differences will be mainly explained.

FIG. 7 to FIG. 17 are top plan views of image sensors according to some embodiments.

Unlike the embodiment shown in FIG. 3, according to embodiments shown in FIG. 7 to FIG. 12, the arrangement shape of grid patterns 310 disposed between the color filters CF is changed.

Unlike the image sensor 100 shown in FIG. 3, in an image sensor 100_1 according to an embodiment shown in FIG. 7, a grid pattern 310, which is disposed between color filters CF with the same color among a plurality of color filters CF, is omitted.

Specifically, referring to FIG. 7, a grid pattern 310 may not be disposed between second color filters CF2 that have the same color among the plurality of color filters CF.

The grid pattern 310 disposed between a first portion CF2a of one of a plurality of second color filters CF2 having the same color and a second portion CF2b of another second color filter CF2 may be omitted. That is, the first portion CF2a of one second color filter CF2 and the second portion CF2b of another second color filter CF2 may contact each other without a portion of the grid pattern 310 therebetween.

Accordingly, at least two second color filters CF2 neighboring each other in a first diagonal direction DR1 are integrated, and there may be no boundary between the second color filters CF2. That is, the first portion CF2a and the second portion CF2b of at least two second color filters CF2 are arranged side by side along the first diagonal direction DR1, and there may be no boundary between them.

In addition, the grid pattern 310 may extend along side surfaces of at least two second color filters CF2 arranged side by side along the first diagonal direction DR1.

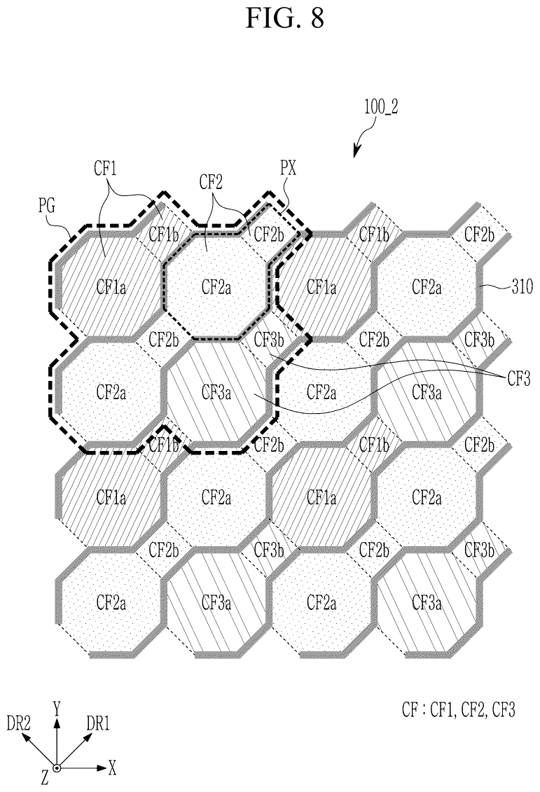

An image sensor 100_2 according to an embodiment shown in FIG. 8 is different from the image sensor 100_1 according to the embodiment shown in FIG. 7 in that a part of a grid pattern 310 disposed between color filters CF with different colors among a plurality of color filters CF is omitted.

Specifically, referring to FIG. 8, a grid pattern 310 may not be disposed between a first color filter CF1 and a third color filter CF3, which have different colors and are adjacent to each other.

A first portion CF1a of a plurality of first color filter CF1 may contact a second portion CF3b of the third color filter CF3, and a second portion CF1b of the plurality of first color filters CF1 may contact a first portion CF3a of the third color filter CF3.

In addition, the first portion CF3a of each of the plurality of third color filters CF3 may be in contact with the second portion CF1b of the first color filter CF1, and the second portion CF3b of the plurality of third color filters CF3 may be in contact with the first portion CF1a of the first color filter CF1.

Accordingly, the grid pattern 310 may extend along side surfaces of the first color filter CF1 and the side surfaces of the third color filter CF3 arranged side by side along the first diagonal direction DR1. For example, the grid pattern 310 may be disposed between two different color filters arranged in the second diagonal direction DR2, without being disposed between two adjacent color filters, irrespective of the same color filter or not, arranged in the first diagonal direction DR1.

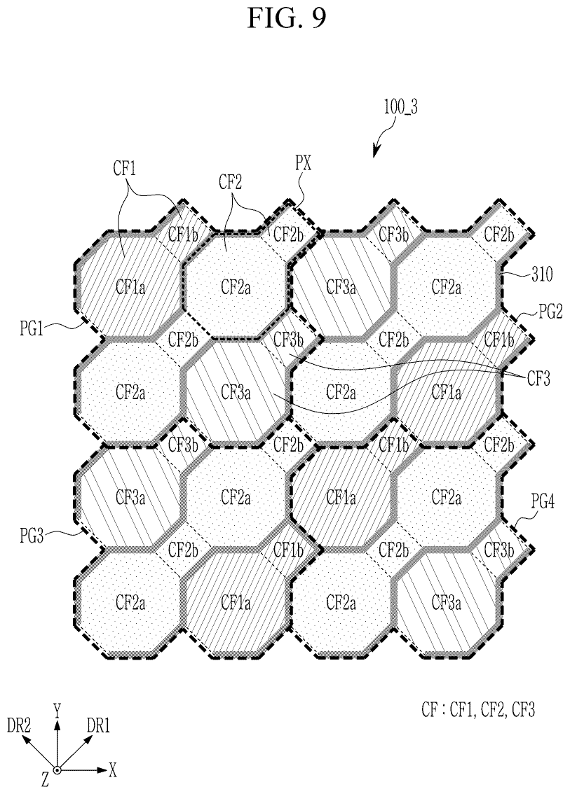

An image sensor 100_3 according to an embodiment shown in FIG. 9 is different from the image sensor 100_2 according to the embodiment shown in FIG. 8 in the arrangement of a plurality of color filters CF.

Specifically, referring to FIG. 9, the image sensor 100_3 according to the present embodiment may include first to fourth pixel groups PG1, PG2, PG3, and PG4. Each of the first to fourth pixel groups PG1 to PG4 may be formed of a plurality of pixels PX.

In the present embodiment, each of the first to fourth pixel groups PG1, PG2, PG3, and PG4 includes four adjacent pixels PX arranged in 2 rows and 2 columns, and the first to fourth pixel groups PG1, PG2, PG3, and PG4 may be arranged in 2 rows and 2 columns.

The arrangement of the plurality of color filters CF included in the first pixel group PG1 may be the same as the arrangement of the plurality of color filters CF included in the fourth pixel group PG4, and the arrangement of the plurality of color filters CF included in the second pixel group PG2 may be the same as the arrangement of color filters CF included in the third pixel group PG3.

The plurality of color filters CF included in each of the first to fourth pixel groups PG1, PG2, PG3, and PG4 may have a Bayer pattern on the plane.

The arrangement of the plurality of color filters CF included in the first pixel group PG1 and the fourth pixel group PG4 may be the same as the arrangement of the color filters CF included in the pixel group PG shown in FIG. 8.

Unlike the color filters CF included in the pixel group PG shown in FIG. 8, the positions of the first color filter CF1 and the third color filter CF3 can be switched in the arrangement of the plurality of color filters CF included in each of the second pixel group PG2 and the third pixel group PG3.

Accordingly, when the first to fourth pixel groups PG1, PG2, PG3, and PG4 are arranged in 2 rows and 2 columns, a plurality of color filters CF with the same color may be arranged side by side along the first diagonal direction DR1.

In the present embodiment, the planar arrangement shape of the grid pattern 310 is substantially the same as the planar arrangement shape of the grid pattern 310 according to the embodiment shown in FIG. 8, and the arrangement of the plurality of color filters CF according to the present embodiment may be different from the arrangement of the plurality of color filters CF according to the embodiment shown in FIG. 8.

That is, the first portion CF1a of any one of the plurality of first color filters CF1 may contact the second portion CF1b of another first color filter CF1, and the first portion CF3a of any one of the plurality of third color filters CF3 may contact the second portion CF3b of another third color filter CF3.

Since the description of a plurality of second color filters CF2 is substantially the same as the description provided above in detail with reference to FIG. 8, no further description will be provided.

Accordingly, the first portions CF1a, CF2a, and CF3a and the second portions CF1b, CF2b, and CF3b included in at least two of the first to third color filters CF1, CF2, and CF3 extending along the first diagonal direction DR1 are arranged side by side along the first diagonal direction DR1, and there may be no boundary between them. That is, each of the first to third color filters CF1, CF2, and CF3 arranged side by side along the first diagonal direction DR1 may be formed as one piece.

In addition, the grid pattern 310 may be disposed between the plurality of first color filter CF1 and the plurality of second color filter CF2, and between the plurality of second color filter CF2 and the plurality of third color filter CF3.

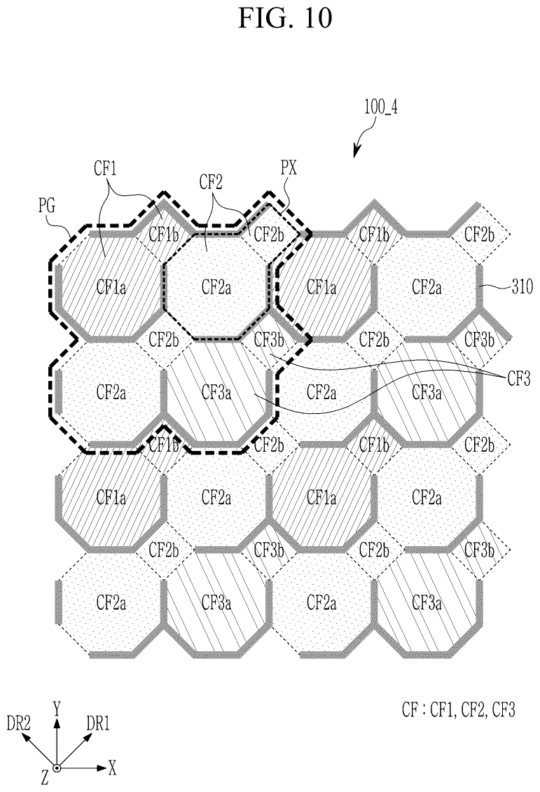

Image sensors 100_4, 100_5, and 100_6 according to embodiments shown in FIG. 10 to FIG. 12 are different from the image sensor 100_1 according to the embodiment shown in FIG. 7 in that a part of the grid pattern 310 disposed between color filters CF having different colors is omitted.

That is, a grid pattern 310 may surround parts of color filters CF such that at least some of side surfaces of second portions CF1b, CF2b, and CF3b of the color filters CF are in contact with first portions CF1a, CF2a, and CF3a of color filters CF having different colors.

Accordingly, at least some of the side surfaces of the second portions CF1b, CF2b, and CF3b of the color filters CF may be in contact with the first portions CF1a, CF2a, and CF3b of the color filters CF having different colors.

Specifically, referring to FIG. 10, the grid pattern 310 may surround a part of a first color filter CF1 such that a part of side surface of the second portion CFb1 of the first color filter CF1 is in contact with the first portion CF2a of the second color filter CF2.

Accordingly, the second portion CF1b of the first color filter CF1 may contact the first portion CF2a of any one of the plurality of second color filters CF2 adjacent to each other.

The grid pattern 310 may surround a portion of the second color filter CF2 such that a side surface of a second portion CF2b of any one of the plurality of second color filters CF2 contacts the first portion CF1a of the first color filter CF1.

The grid pattern 310 may surround a portion of the second color filter CF2 such that a part of a side surface of a second portion CF2b of another one of the plurality of second color filters CF2 contacts the first portion CF3a of the third color filter CF3.

Accordingly, the second portion CF2b of any one of the plurality of second color filters CF2 may contact the first portion CF1a of the first color filter CF1 and the first portion CF2a of another second color filters CF2.

In addition, the second portion CF2b of one of the plurality of second color filters CF2 may contact the first portion CF3a of the third color filter CF3 and the first portion CF2a of another second color filter CF2.

The grid pattern 310 may surround a portion of the third color filter CF3 such that some of the side surfaces of the second portion CF3b of the third color filter CF3 are in contact with the first portion CF2a of the second color filter CF2.

Accordingly, the second portion CF3b of the third color filter CF3 may contact a first portion CF2a of any one of the plurality of second color filters CF2 adjacent to each other.

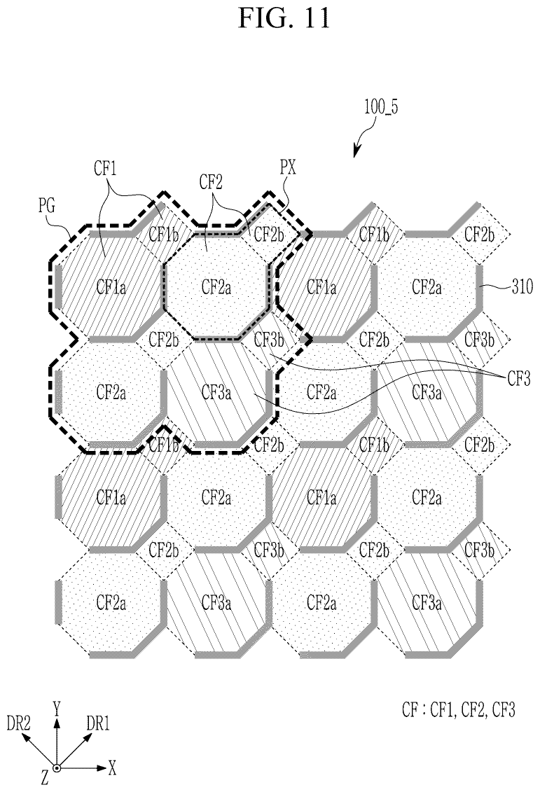

Referring to FIG. 11, a grid pattern 310 may surround a part of a first color filter CF1 such that one of side surfaces of second portions CF1b of the first color filter CF1 contacts a first portion CF2a of a second color filter CF2 adjacent to the first color filter CF1 in the first direction X and another side surface contacts a first portion CF3a of a third color filter CF3 adjacent to the first color filter CF1 in the first diagonal direction DR1.

Accordingly, the second portion CF1b of the first color filter CF1 may contact the first portion CF2a of any one of the plurality of second color filters CF2 adjacent to the first color filter CF1 and the first portion CF3a of the third color filter CF3 adjacent to the first color filter CF1.

The arrangement relationship between the grid pattern 310 and the plurality of second color filters CF2 is substantially the same as the embodiment shown in FIG. 10, and therefore description thereof is omitted.

The grid pattern 310 may surround a part of the third color filter CF3 such that one of side surfaces of the second portion CF3b of the third color filter CF3 is in contact with the first portion CF2a of the second color filter CF2, and another side surface is in contact with the first portion CF1a of the first color filter CF1.

Accordingly, the second portion CF3b of the third color filter CF3 may contact a first portion CF2a of any one of the plurality of second color filters CF2 adjacent to the third color filter CF3 in the first direction X and the first portion CF1a of the first color filter CF1 adjacent to the third color filter CF3 in the first diagonal direction DR1.

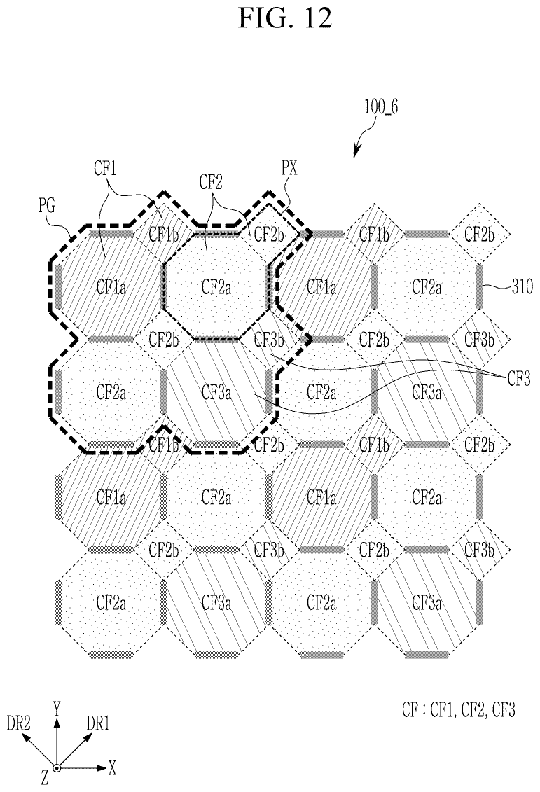

Referring to FIG. 12, in the present embodiment, a grid pattern 310 may surround some of color filters CF such that all side surfaces of second portions CF1b, CF2b, and CF3b of the color filters CF contact first portions CF1a, CF2a, and CF3a of color filters CF having the same or different colors.

That is, the grid pattern 310 may not be disposed on all side surfaces of each of the second portions CF1b, CF2b, and CF3b of the color filters CF.

The grid pattern 310 may extend along side surfaces that are not in contact with the second portions CF1b, CF2b, and CF3b among the side surfaces of each of the first portions CF1a, CF2a, and CF3a of the color filters CF.

The grid pattern 310 may be disposed between two adjacent first portions of the first portions CF1a, CF2a, and CF3a of the color filters CF having different colors. That is, the grid pattern 310 may be arranged in an island shape on a plane. In an embodiment, the grid pattern 310 may include at least two island-shape portions that contact at least two sides of a first portion of a color filter, respectively. For example, in FIG. 12, a first portion CF1a of the first color filter CF1 may have four sides which contact four island-shape portions of the grid pattern 310, respectively. The four island-shape portions may be separated from each other.

Accordingly, the second portion CF1b, which is in contact with the first portion CF1a of the first color filter CF1, may be in contact with the first portion CF2a of each of the two adjacent second color filter of the plurality of second color filters CF2 and the first portion CF3a of the third color filter CF3.

The second portion CF2b of the second color filter CF2 may contact the first portions CF2a of each of the two adjacent second color filter CF2, the first portion CF1a of the first color filter CF1, and the first portion CF3a of the third color filter CF3.

The second portion CF3b, which is in contact with the first portion CF3a of the third color filter CF3, may be in contact with the first portions CF2a of each of the two adjacent second color filters CF2, and the first portion CF1a of the first color filter CF1.

The arrangement of the grid patterns 310 disposed between the plurality of color filters CF is not limited to the above-described embodiments and may be changed in various ways.

In the image sensors 100_1, 100_2, 100_3, 100_4, 100_5, and 100_6 according to some embodiments, the arrangement of the grid pattern 310 may be changed in various ways to have substantially the same effect as the image sensor 100 according to an embodiment.

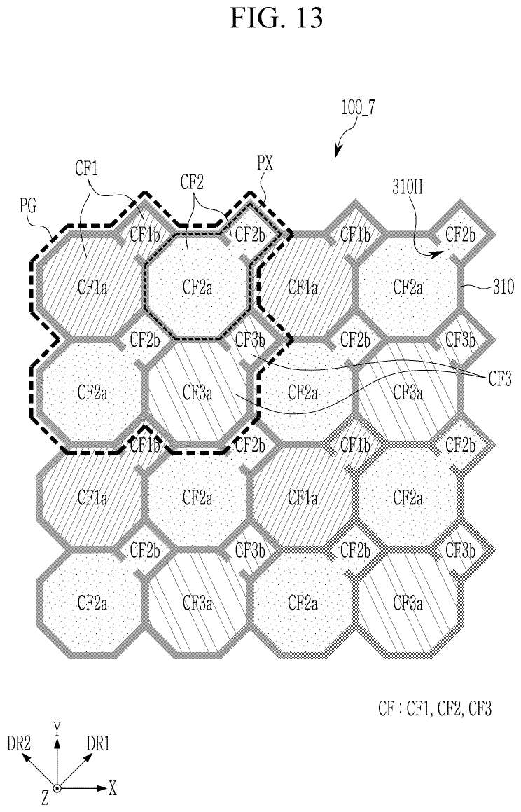

Embodiments of the image sensor 100_7, 100_8, 100_9, and 100_10 shown in FIG. 13 to FIG. 16 are different from the embodiments shown in FIG. 3 and FIG. 7 to FIG. 12 in that a grid pattern 310 is partially disposed between first portions CF1a, CF2a, and CF3a of color filters CF with different colors and second portions CF1b, CF2b, and CF3b, and the grid pattern 310 includes an open portion 310H where a junction portion in which the first portions CF1a, CF2a, and CF3a and second portions CF1b, CF2b, and CF3b of the color filters CF are in contact with each other is disposed.

The image sensor 100_7 according to the embodiment shown in FIG. 13 is different from the image sensor 100 according to the embodiment shown in FIG. 3 in that a grid pattern 310 may be partially disposed between first portions CF1a, CF2a, and CF3a and second portions CF1b, CF2b, and CF3b included in each color filter CF.

The grid pattern 310, which is partially disposed between the first portions CF1a, CF2a, and CF3a and the second portions CF1b, CF2b, and CF3b included in each of the color filters CF, may extend along a part of side surfaces of the first portions CF1a, CF2a, and CF3a and a part of side surfaces of the second portions CF1b, CF2b, and CF3b which are adjacent to the first portions CF1a, CF2a, and CF3a, respectively.

The grid pattern 310 may include open portions 310H, and junction portions in which the first portions CF1a, CF2a, and CF3a and the second portions CF1b, CF2b, and CF3b are in contact with each other may be disposed in the open portions 310H. The junction portions are disposed between the first portions CF1a, CF2a, and CF3a and the second portions CF1b, CF2b, and CF3b included in each color filter CF. In an embodiment, the grid pattern 310 may include a first pattern portion surrounding each pixel and two second pattern portions extending from the first pattern portion. The two second pattern portions may be spaced apart from each other to define the grid pattern 310. Each of the two second pattern portions may be disposed between the first and second portions of the pixel or at the boundary therebetween. For example, in the first pixel CF1, the two second pattern portions may be disposed between the first and second portions CF1a and CF1b.

In the open portions 310H of the grid pattern 310, parts of the first portions CF1a, CF2a, and CF3a and parts of the second portions CF1b, CF2b, and CF3b included in each color filter CF may contact each other. That is, in the open portions 310H of the grid pattern 310, junction portions where parts of the side surface of the first portions CF1a, CF2a, and CF3a and parts of the side surface of the second portions CF1b, CF2b, and CF3b included in each of the color filters CF are in contact with each other may be disposed.

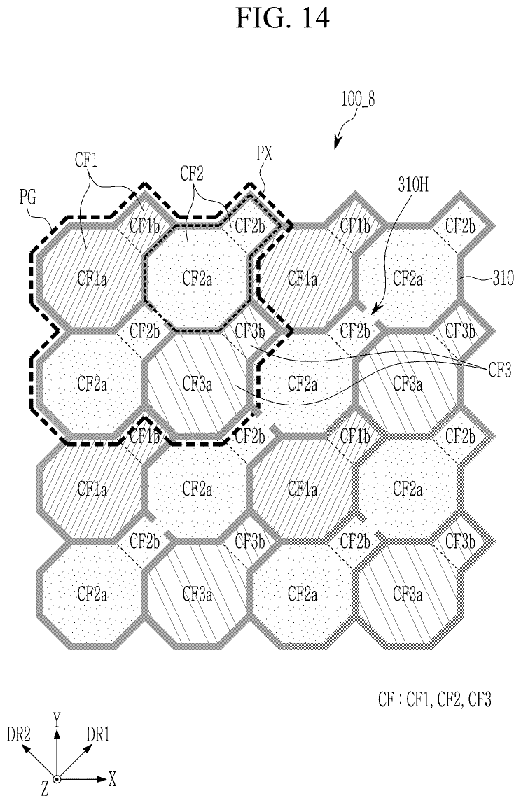

The image sensor 100_8 according to the embodiment shown in FIG. 14 is different from the image sensor 100_1 shown in FIG. 7 in that the grid pattern 310 is partially disposed between one color filter and another color filter CF among the color filters CF having the same color.

In detail, referring to FIG. 14, a grid pattern 310 partially disposed between a first portion CF2a of one of a plurality of second color filters CF2 and a second portion CF2b of another second color filter CF2 may extend along a part of a side surface of a first portion CF2a and a part of a side surface of a second portion CS2b, which are adjacent to each other.

The grid pattern 310 may include an open portion 310H where a junction portion where a first portion CF2a of one of the plurality of second color filters CF2 and a second portion CF2b of another second color filter CF2 are in contact with each other.

In the open portion 310H of the grid pattern 310, a junction portion where a part of the first portion CF2a of one of the plurality of second color filters CF2 and a part of a second portion CF2b of another second color filter CF1 contact each other may be disposed.

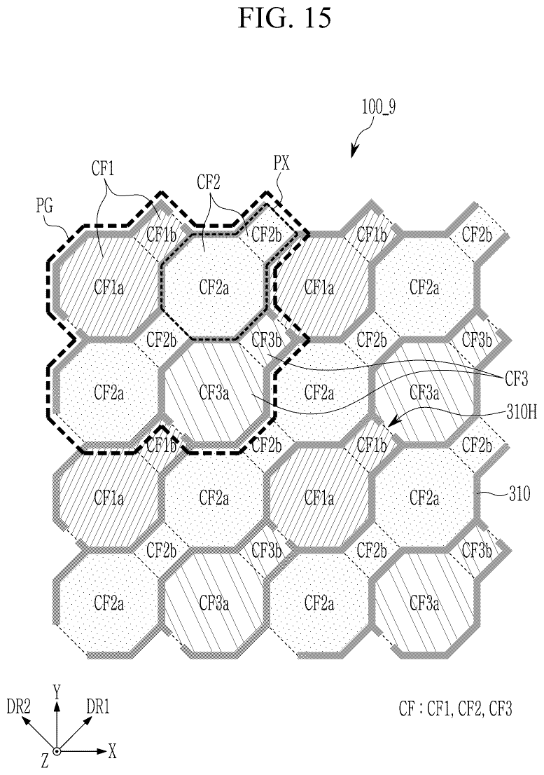

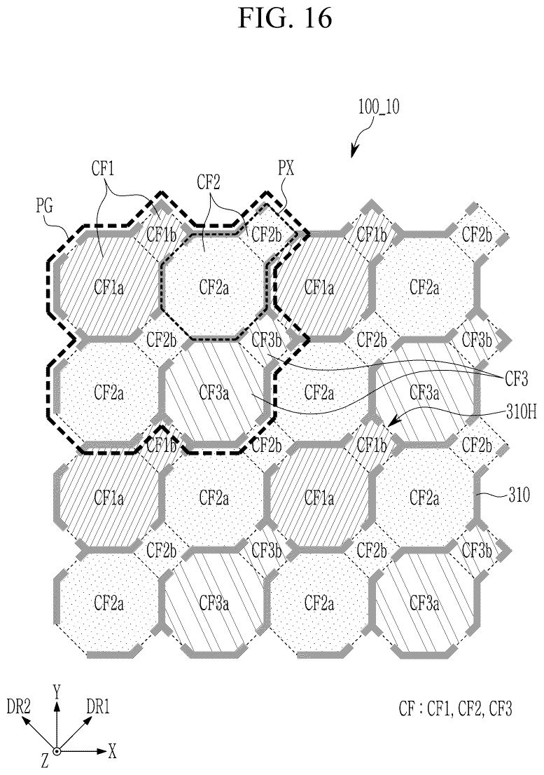

In the image sensors 100_9 and 100_10 according to the embodiments of FIG. 15 and FIG. 16, a grid pattern 310 may be partially disposed between color filters CF with different colors.

The image sensor 100_9 according to the embodiment shown in FIG. 15 is different from the image sensor 100_1 shown in FIG. 7 in that the grid pattern 310 is partially disposed between one color filter CF and another color filter CF among color filters CF with different colors.

Specifically, referring to FIG. 15, the grid pattern 310 is partially disposed between a first portion CF1a of a first color filter CF1 and a second portion CF3b of a third color filter CF3, and the grid pattern 310 may include an open portion 310H where a junction in which the first portion CF1a of the first color filter CF1 and the second portion CF3b of the third color filter CF3 contact each other is disposed.

In addition, the grid pattern 310 is partially disposed between a second portion CF1b of the first color filter CF1 and a first portion CF3a of the third color filter CF3, and the grid pattern 310 may include an open portion 310H where a junction in which the second portion CF1b of the first color filter CF1 and the first portion CF3a of the third color filter CF3 contact each other is disposed.

A junction in which a part of the first portion CF1a of the first color filter CF1 and a part of the second portion CF2b of the second color filter CF2 contact each other, and a junction in which a part of the second portion CF1b of the first color filter CF1 and a part of the first portion CF3a of the third color filter CF3 contact each other may be disposed in the open portion 310H of the grid pattern 310.

Unlike the image sensor 100_9 shown in FIG. 15, in the image sensor 100_10 according to the embodiment shown in FIG. 16, a grid pattern 310 may further be partially disposed between a second portion CF1b of a first color filter CF1 and a first portion CF2a of a second color filter CF2, between a second portion CF2b of the second color filter CF2 and a first portion CF1a of first color filter CF1, between the second portion CF2b of the second color filter CF2 and a first portion CF3a of a third color filter CF3, and between a second portion CF3b of the third color filter CF3 and the first portion CF1a of the first color filter CF1, respectively. The first to third color filters CF1 to CF3 may be adjacent to each other.

The grid pattern 310 may include an open portion 310H where a junction portion where first portions CF1a, CF2a, and CF3a and second portions CF1b, CF2b, and CF3b of color filters CF having different colors are in contact with each other is disposed.

In the open portion 310H of the grid pattern 310, a junction portion where a portion of each of the first portions CF1a, CF2a, and CF3a and a portion of each of the second portions CF1b, CF2b, and CF3b of the color filters CF having different colors are in contact with each other may be disposed.

In the image sensors 100_7, 100_8, 100_9, and 100_10 according to some embodiments, the arrangement of the grid pattern 310 may be changed in various ways to have substantially the same effect as the image sensor 100 according to an embodiment.

In addition, as the grid pattern 310 is partially disposed between the plurality of color filters CF having the same color or different colors, the crosstalk phenomenon between the plurality of color filters CF can be reduced.

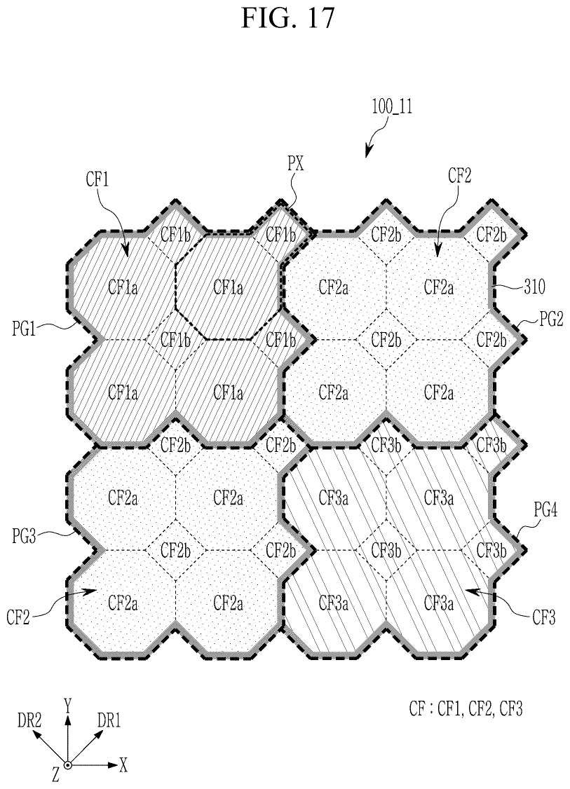

An image sensor 100_11 according to an embodiment shown in FIG. 17 is different from the image sensor 100 according to the embodiment shown in FIG. 3 in the arrangement of a plurality of color filters CF.

Specifically, referring to FIG. 17, a plurality of color filters CF may include a first color filter CF1 disposed to correspond to a first pixel group PG1, a second color filter CF2 disposed to correspond to a second pixel group PG2, a second color filter CF2 disposed to correspond to a third pixel group PG3, and a third color filter CF3 disposed to correspond to a fourth pixel group PG4.

The first to third color filters CF1, CF2, and CF3 may include a plurality of first portions CF1a, CF2a, and CF3a and a plurality of second portions CF1b, CF2b, and CF3b disposed respectively to correspond to a first pixel region (refer to PR1 of FIG. 1) and a second pixel region (refer to PR2 of FIG. 4) of a plurality of pixels PX.

In the present embodiment, the grid pattern 310 may be disposed between the plurality of color filters CF. That is, the grid pattern 310 may entirely surround each of the first color filter CF1 disposed to correspond to the first pixel group PG1, the second color filter CF2 disposed to correspond to the second pixel group PG2, the second color filter CF2 disposed to correspond to the third pixel group PG3, and the third color filter CF3 disposed to correspond to the pixel group PG4.

Accordingly, the grid pattern 310 may be disposed between a plurality of color filters CF having different colors.

The grid pattern 310 may not be disposed within the plurality of color filters CF. For example, the grid pattern 310 may not be disposed between the first portion CF1a of the first color filter CF1 and the second portion CF1b of the first color filter CF1. That is, the first portions CF1a of the first color filter CF1 may contact each other, and the first portions CF1a and the second portions CF1b of the first color filter CF1 may contact each other.

Although the first color filter CF1 is used as a reference, the above description may be applied substantially the same to the second color filter CF2 and the third color filter CF3.

Although not shown, in some embodiments, the grid pattern 310 may be disposed within the plurality of color filters CF. For example, the grid pattern 310 may be disposed between the first portion CF1a of the first color filter CF1, and the grid pattern 310 may not be disposed between the first portion CF1a and the second portion CF1b of the first color filter CF1.

Although the first color filter CF1 is used as a reference, the above description may be applied substantially the same to the second color filter CF2 and the third color filter CF3.

The image sensor 100_11 according to the present embodiment may have substantially the same effect as the image sensor 100 according to the present embodiment.

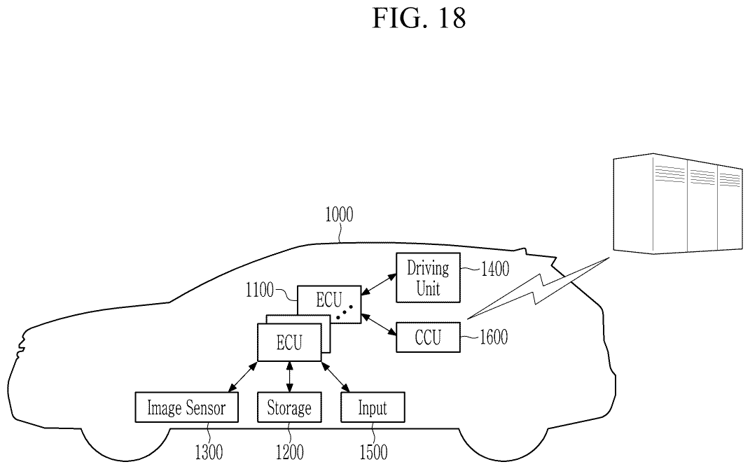

FIG. 18 shows a vehicle including the image sensor according to some embodiments.

Referring to FIG. 18, a vehicle 1000 may include a plurality of electron control units (ECU) 1100 and a storage device 1200.

Each electron control device of the plurality of electron control device 1100 is electrically, mechanically, and communicationally connected to at least one device among a plurality of devices provided in the vehicle 1000, and operates the at least one device based on a function performance instruction.

Here, the plurality of devices may include an image sensor 1300 that acquires an image required to perform at least one function and a driving unit 1400 that performs at least one function.

For example, the image sensor 1300 of FIG. 18 may include the image sensor disposed above with reference to FIG. 1 to FIG. 17.

The driving unit 1400 may include a fan and compressor of an air conditioning device, a fan of a ventilation device, an engine and a motor of a power device, a motor of a steering device, a motor and a valve of a braking device, and a door or tail gate opening and closing device.

The plurality of electron control devices 1100 may communicate with the image sensor 1300 and the driving unit 1400 using at least one of, for example, Ethernet, low voltage differential signal (LVDS) communication, and LIN (Local Interconnect Network) communication.

The plurality of electron control devices 1100 determine whether it is necessary to perform a function based on information acquired through the image sensor 1300, and when it is determined that performance of the function is necessary, the devices 1100 control the operation of the driving unit 1400 that performs the function, while controlling the amount of operation of the driving unit 1400 based on information.

Here, the plurality of electron control device 1100 may store the acquired image in the storage device 1200 or read and use information stored in the storage device 1200.

The plurality of electron control device 1100 is also capable of controlling the operation of the driving unit 1400 that performs the function based on a function performance instruction input through an input portion 1500, and checks a set amount of settings corresponding to information input through the input portion 1500 and controls the operation of the driving unit 1400, which performs the corresponding function based on the checked set amount.

Each electron control device 1100 may control one function independently or may control one function in conjunction with another electron control device. For example, the electron control device of a collision prevention device can output a warning sound about collision with an obstacle through a speaker when a distance to the obstacle detected through a distance detector is within a reference distance.

An electron control device of an autonomous driving control device receives navigation information, road image information, and information of a distance to obstacles in conjunction with an electron control device of a vehicle terminal, an electron control device of an image acquisition portion, and an electron control device of a collision prevention device, and controls a power device, a braking system, and a steering system using the received information, thereby performing autonomous driving.

A connectivity control unit (CCU) 1600 is electrically, mechanically, and communicatively connected to each of the plurality of electron control devices 1100, and may perform communication with each of the plurality of electron control devices 1100.

That is, the connectivity control device 1600 may communicate directly with the plurality of electron control devices 1100 provided inside the vehicle, communicate with an external server, and communicate with an external terminal through an interface.

Here, the connectivity control device 1600 may communicate with the plurality of electron control devices 1100 and communicate with the server 2000 using an antenna (not shown) and RF communication.

In addition, the connectivity control device 1600 may communicate with the server 2000 through wireless communication. Here, wireless communication between the connection control device 1600 and the server 2000 may be carried out through various wireless communication methods such as a global system for mobile communication (GSM), code division multiple access (CDMA), and wideband code division multiple access (WCDMA), a universal mobile telecommunications system (UMTS), time division multiple access (TDMA), and long term evolution (LTE) may be possible through various wireless communication methods in addition to a Wi-Fi module and a wireless broadband module.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An image sensor comprising:
a substrate;
a first photodiode disposed in the substrate;
a second photodiode disposed in the substrate, wherein the second photodiode is adjacent to the first photodiode and is different from the first photodiode in planar area;
a pixel isolation pattern that is disposed between the first photodiode and the second photodiode;
a color filter disposed continuously above the first photodiode and the second photodiode; and
a grid pattern that surrounds at least a part of the color filter,
wherein the color filter comprises a first portion overlapping the first photodiode in a first direction perpendicular to an upper surface of the substrate and a second portion overlapping the second photodiode in the first direction, and
a thickness of a junction portion where the first portion and the second portion of the color filter contact each other in the first direction corresponds to a thickness, in the first direction, of one of the first portion and second portion.

2. The image sensor of claim 1, wherein:
the first portion and the second portion of the color filter have the same color.

3. The image sensor of claim 2, wherein:
the grid pattern contacts at least one side surface of side surfaces of the first portion and at least one side surface of side surfaces of the second portion of the color filter.

4. The image sensor of claim 3, wherein:
the one side surface of the side surfaces of the first portion contacts an entirety of the one side surface of the side surfaces of the second portion.

5. The image sensor of claim 1, wherein:
the grid pattern includes at least two island-shaped portions separated from each other when viewed in a plan view, and
each of the at least two island-shaped portions contacts a corresponding one of at least two side surfaces of side surfaces of the first portion of the color filter when viewed in a plan view.

6. The image sensor of claim 1, wherein:
the color filter comprises:
a plurality of first color filters having a first color;
a plurality of second color filters having a second color; and
a plurality of third color filters having a third color,
each of the plurality of first to third color filters includes the first portion and the second portion, and
the first portion of one of the plurality of first color filters contacts the second portion of another first color filters.

7. The image sensor of claim 6, wherein:
the second portion of one of the plurality of first color filters contacts at least one of the first portion of one of the plurality of second color filters and the first portion of one of the plurality of third color filters.

8. The image sensor of claim 7, wherein:
second portions of the plurality of second color filters and second portions of the plurality of third color filters contact first portions of the plurality of first color filters, respectively.

9. The image sensor of claim 8, wherein:
the first portion of one of the plurality of second color filters contacts the second portion of one of the plurality of third color filters, and
the second portion of one of the plurality of second color filters contacts the first portion of another one of the plurality of third color filters.

10. The image sensor of claim 9, wherein:
the second portions of the plurality of first color filters contact the first portions of the plurality of second color filters and the first portions of the plurality of third color filters.

11. The image sensor of claim 6, wherein:
the first portion of any one of the plurality of second color filters contacts the second portion of another one of the plurality of second color filters, and
the second portion of any one of the plurality of third color filters contacts the second portion of another one of the plurality of third color filters.

12. The image sensor of claim 6, wherein:
the grid pattern is disposed between the plurality of first color filters and the plurality of second color filters, between the plurality of first color filters and the plurality of third color filters, and between the plurality of second color filters and the plurality of third color filters.

13. An image sensor comprising:
a substrate;
a first photodiode disposed in the substrate;
a second photodiode disposed in the substrate, wherein the second photodiode is adjacent to the first photodiode and is different from the first photodiode in planar area;
a pixel isolation pattern that is disposed between the first photodiode and the second photodiode;
a color filter disposed continuously above the first photodiode and the second photodiode; and
a grid pattern that surrounds at least a part of the color filter,
wherein the color filter comprises a first portion overlapping the first photodiode and a second portion overlapping the second photodiode,
wherein the grid pattern comprises a first pattern portion and a second pattern portion spaced apart from each other to define a first open portion of the grid pattern,
wherein each of the first and second pattern portions is disposed between the first and second portions of the color filter, and
wherein a junction portion at which the first portion and the second portion contact each other is disposed in the first open portion of the grid pattern.

14. The image sensor of claim 13, wherein:
one side surface of side surfaces of the first portion of the color filter contacts an entirety of one side surface of side surfaces of the second portion of the color filter.

15. The image sensor of claim 13, wherein:
the color filter comprises:
a plurality of first color filters having a first color;
a plurality of second color filters having a second color; and
a plurality of third color filters having a third color,
each of the plurality of first to third color filters includes the first portion and the second portion, and
the first portions of plurality of first to third color filters contact the second portions thereof, respectively.

16. The image sensor of claim 15, wherein:
the first open portion of the grid pattern is disposed between the first portion and the second portion of each of the plurality of first to third color filters when viewed in the plan view.

17. The image sensor of claim 15, wherein:
the grid pattern further includes a second open portion which is disposed between the first portion of any one of the plurality of first color filters and the second portion of another one of the plurality of first color filters.

18. The image sensor of claim 15, wherein:
the grid pattern further includes a second open portion which is disposed between the first portion of any one of the plurality of second color filters and the second portion of any one of the plurality of third color filters, and a third open portion which is disposed between the second portion of any one of the plurality of second color filters and the first portion of another one the plurality of third color filters.

19. The image sensor of claim 18, wherein:
the grid pattern further includes a fourth open portion which is disposed between the first portion of any one of the plurality of first color filters and second portion of any one of the plurality of second color filters,
a fifth open portion which is disposed between the first portion of any one of the plurality of first color filters and the second portion of any one of the plurality of third color filters,
a sixth open portion which is disposed between the second portion of any one of the plurality of first color filters and the first portion of any one of the plurality of second color filters, and
a seventh open portion which is disposed between the second portion of any one of the plurality of first color filters and the first portion of any one of the plurality of third color filters.

20. An image sensor comprising:
a substrate including a first side and a second side that face each other;
a first photodiode disposed in the substrate;
a second photodiode disposed in the substrate, wherein the second photodiode is adjacent to the first photodiode and is different from the first photodiode in planar area;
a pixel isolation pattern that is disposed between the first photodiode and the second photodiode;
a color filter disposed on the first side of the substrate and disposed continuously above the first photodiode and the second photodiode;
a grid pattern that surrounds at least a part of the color filter; and
a micro lens layer disposed on the color filter,
wherein the color filter comprises a first portion overlapping the first photodiode in a first direction perpendicular to the first side of the substrate and a second portion overlapping the second photodiode in the first direction,
a thickness of a junction portion where the first portion and the second portion of the color filter contact each other in the first direction is greater than or substantially equal to a thickness, in the first direction, of the grid pattern, and
wherein the micro lens layer includes:
a first micro lens disposed on the first portion of the color filter, and
a second micro lens disposed on the second portion of the color filter and having a height that is different from a height of the first micro lens.
